(19) United States
(12) Patent Application Publication
(10) Pub. No.: US 2025/0386561 A1
(43) Pub. Date: Dec. 18, 2025

(54) SEMICONDUCTOR DEVICE

(71) Applicant: SAMSUNG ELECTRONICS CO., LTD., Suwon-si (KR)

(72) Inventors: Ki-Il KIM, Suwon-si (KR); Kyong Beom Koh, Suwon-si (KR); Gwan Ho Kim, Suwon-si (KR); Ki Hwan Kim, Suwon-si (KR); Hyon Wook Ra, Suwon-si (KR); Hyung Goo Lee, Suwon-si (KR)

(73) Assignee: SAMSUNG ELECTRONICS CO., LTD., Suwon-si (KR)

(21) Appl. No.: 19/026,877

(22) Filed: Jan. 17, 2025

(30) Foreign Application Priority Data
Jun. 18, 2024 (KR) 10-2024-0078662

(51) Int. Cl. H10D 62/10; H10D 30/01; H10D 30/43; H10D 30/67; H10D 62/832; H10D 64/01; H10D 64/23

(52) U.S. Cl. CPC H10D 62/116; H10D 30/43; H10D 30/6735; H10D 30/6757; H10D 62/832; H10D 64/256; H10D 30/014; H10D 62/121; H10D 64/018

(57) ABSTRACT

A semiconductor device includes a back interlayer insulating film; active patterns that extend in a first direction on the back interlayer insulating film; gate structures that extend in a second direction on the active patterns; recesses that are in the active patterns and are on a side of the gate structures; source/drain spacers in the recesses; source/drain patterns that are in the recesses and are on the source/drain spacers; and back source/drain contacts that extend in a third direction from the back interlayer insulating film toward the source/drain patterns, and are connected to the source/drain patterns, wherein the source/drain spacers include different materials from each other.

### CROSS-REFERENCE TO RELATED APPLICATION

This application claims priority from Korean Patent Application No. 10-2024-0078662 filed on Jun. 18, 2024, in the Korean Intellectual Property Office, the contents of which in its entirety are herein incorporated by reference.

### BACKGROUND

### 1. Field

Embodiments of the present disclosure relate to a semiconductor device.

### 2. Description of the Related Art

As one of scaling technologies for increasing density of a semiconductor device, a multi gate transistor in which a multi-channel active pattern (or a silicon body) having a fin or nanowire shape is formed on a substrate and a gate is formed on a surface of the multi-channel active pattern has been proposed.

Since such a multi gate transistor utilizes a three-dimensional channel, scaling is easily performed. Further, even if a gate length of the multi gate transistor is not increased, current control capability may be improved. Furthermore, a short channel effect (SCE) in which potential of a channel region is influenced by a drain voltage may be effectively suppressed.

On the other hand, as a pitch size of semiconductor devices decreases, there is a need for research for reducing the capacitance between contacts in the semiconductor device and ensuring electrical stability.

### SUMMARY

According to example embodiments of the present disclosure, a semiconductor device is provided that may improve element performance and reliability.

According to example embodiments of the present disclosure, a semiconductor device may be provided and include: a back interlayer insulating film; a first active pattern that extends in a first direction and is on the back interlayer insulating film; a first gate structure that extends in a second direction, intersecting the first direction, and is on the first active pattern; a first recess that is in the first active pattern and is on a side of the first gate structure; a first source/drain spacer in the first recess; a first source/drain pattern that is in the first recess and is on the first source/drain spacer; a first back source/drain contact that extends in a third direction from the back interlayer insulating film toward the first source/drain pattern, and is connected to the first source/drain pattern; a second active pattern that extends in the first direction and is on the back interlayer insulating film; a second gate structure that extends in the second direction and is on the second active pattern; a second recess that is in the second active pattern and is a side of the second gate structure; a second source/drain spacer in the second recess; a second source/drain pattern that is in the second recess and is on the second source/drain spacer; and a second back source/drain contact that extends in the third direction from the back interlayer insulating film toward the second source/drain pattern, and is connected to the second source/drain pattern, wherein the first source/drain spacer includes a material different from a material of the second source/drain spacer.

According to example embodiments of the present disclosure, a semiconductor device may be provided and include: a back interlayer insulating film; a first back wiring line in the back interlayer insulating film; a second back wiring line in the back interlayer insulating film; a first active pattern that extends in a first direction and is on the first back wiring line; a first gate structure that extends in a second direction, interesting the first direction, and is on the first active pattern; a first source/drain pattern that includes an impurity of a first conductivity type and is on a side of the first gate structure; a first source/drain spacer that extends along a bottom face of the first source/drain pattern; a first back source/drain contact that connects the first back wiring line and the first source/drain pattern; a second active pattern that extends in the first direction and is on the second back wiring line; a second gate structure that extends in the second direction and is on the second active pattern; a second source/drain pattern that includes an impurity of a second conductivity type, different from the first conductivity type, and is on a side of the second gate structure; a second source/drain spacer that extends along a bottom face of the second source/drain pattern; and a second back source/drain contact that connects the second back wiring line and the second source/drain pattern.

According to example embodiments of the present disclosure, a semiconductor device may be provided and include: a back interlayer insulating film; a first back wiring line in the back interlayer insulating film; a second back wiring line in the back interlayer insulating film; a plurality of first sheet patterns spaced apart from each other on the first back wiring line; a first gate structure that surrounds the plurality of first sheet patterns; a first source/drain pattern that is connected to the plurality of first sheet patterns, includes an impurity of a first conductivity type, and is on a side of the first gate structure; a first source/drain spacer that extends along a bottom face of the first source/drain pattern; a first back source/drain contact that connects the first back wiring line and the first source/drain pattern; a plurality of second sheet patterns spaced apart from each other on the second back wiring line; a second gate structure that surrounds the plurality of second sheet patterns; a second source/drain pattern that is connected to the plurality of second sheet patterns, includes an impurity of a second conductivity type different from the first conductivity type, and is on a side of the second gate structure; a second source/drain spacer that extends along a bottom face of the second source/drain pattern; and a second back source/drain contact that connects the second back wiring line and the second source/drain pattern, wherein the first source/drain spacer includes a material different from a material of the second source/drain spacer.

However, aspects of embodiments of the present disclosure are not limited to the ones set forth herein. The above and other aspects of embodiments of the present disclosure will become more apparent to one of ordinary skill in the art to which the present disclosure pertains by referencing the detailed description of the present disclosure given below.

### BRIEF DESCRIPTION OF DRAWINGS

The above and other aspects and features of the present disclosure will become more apparent by describing in detail non-limiting example embodiments thereof with reference to the attached drawings, in which:

FIG. 1 is an example layout view for explaining a semiconductor device according to some embodiments;

FIG. 2 is a cross-sectional view taken along a line A1-A1 and a line A2-A2 of FIG. 1;

FIG. 3 is a cross-sectional view taken along a line B1-B1 and a line B2-B2 of FIG. 1;

FIG. 4 is a cross-sectional view taken along a line C1-C1 and a line C2-C2 of FIG. 1;

FIGS. 5 to 12 are diagrams for explaining a semiconductor device according to some embodiments;

FIGS. 13 to 15 are diagrams for explaining a semiconductor device according to some embodiments;

FIGS. 16 and 17 are diagrams for explaining a semiconductor device according to some embodiments;

FIGS. 18 to 21 are diagrams for explaining intermediate stages of a method for fabricating the semiconductor device according to some embodiments; and

FIG. 22 is an intermediate stage diagram for explaining the method for fabricating the semiconductor device according to some embodiments.

### DETAILED DESCRIPTION

Hereinafter, non-limiting example embodiments of the present disclosure will be described in detail with reference to the accompanying drawings. However, the present disclosure is not limited to the example embodiments described below, and embodiments of the present disclosure may have various other forms. The following example embodiments are provided to sufficiently convey the scope of the present disclosure to those skilled in the art.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

Although the attached drawings show a semiconductor device of some embodiments that includes a fin-type transistor (FinFET) including a channel region of a fin-type pattern shape, a transistor including a nanowire or a nanosheet, and a multi-bridge channel field effect transistor (MBCFET™) as an example, embodiments of the present disclosure are not limited thereto.

The semiconductor device according to some embodiments may include a tunneling transistor (e.g., tunneling FET), a three-dimensional (3D) transistor or a vertical transistor (e.g., Vertical FET). The semiconductor device according to some embodiments may include a planar transistor. In addition, the semiconductor device according to some embodiments may include a transistor based on two-dimensional material (e.g., 2D material based FETs) and a heterostructure thereof.

Further, the semiconductor device according to some embodiments may also include a bipolar junction transistor, a laterally diffused metal oxide semiconductor (LDMOS), or the like.

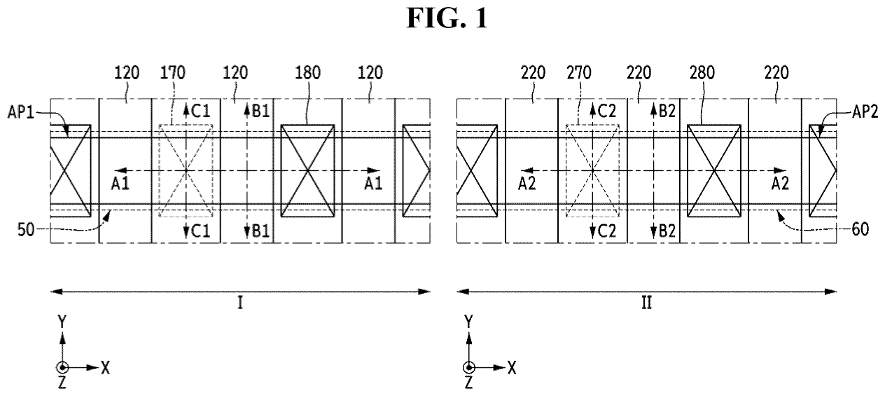

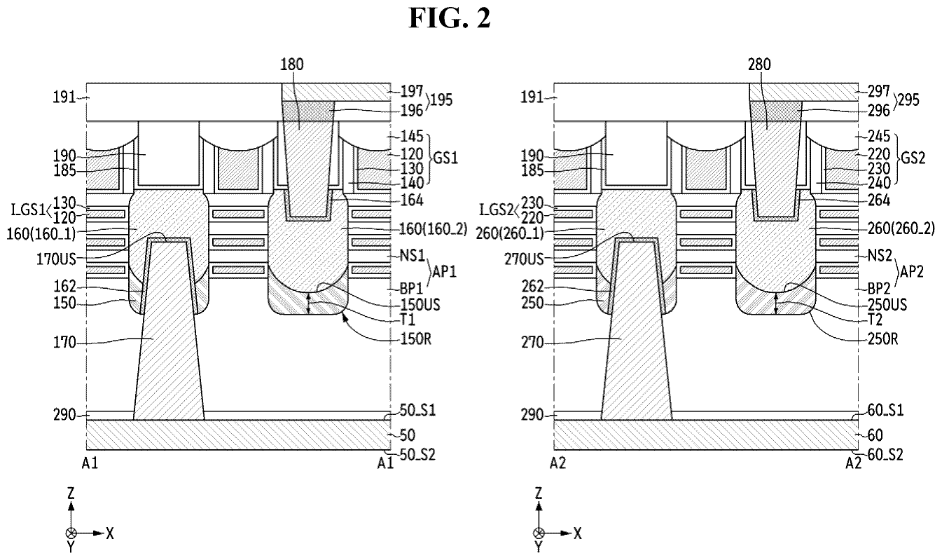

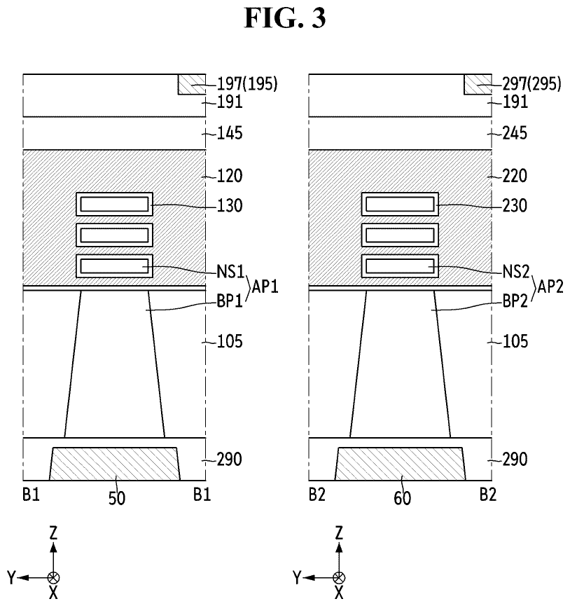

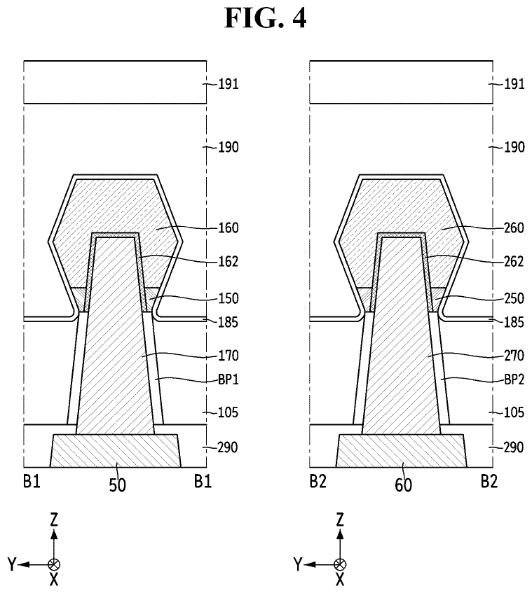

FIG. 1 is an example layout view for explaining a semiconductor device according to some embodiments. FIG. 2 is a cross-sectional view taken along A1-A1 and A2-A2 of FIG. 1. FIG. 3 is a cross-sectional view taken along B1-B1 and B2-B2 of FIG. 1. FIG. 4 is a cross-sectional view taken along C1-C1 and C2-C2 of FIG. 1.

Referring to FIGS. 1 to 4, the semiconductor device according to some embodiments may include a first active pattern AP1, a second active pattern AP2, a first gate structure GS1, a second gate structure GS2, a first source/drain spacer 150, a first source/drain pattern 160, a second source/drain spacer 250, a second source/drain pattern 260, a first back source/drain contact 170, a second back source/drain contact 270, a first front source/drain contact 180, a second front source/drain contact 280, a first back wiring line 50, a second back wiring line 60, a first front wiring structure 195, and a second front wiring structure 295. According to embodiments of the present disclosure, “source/drain” may refer to a source and/or drain of a transistor.

The semiconductor device according to some embodiments includes a first region I and a second region II in which transistors of different conductivity types from each other are formed. For example, a p-type transistor may be formed in the first region I, and an n-type transistor may be formed in the second region II.

The first active pattern AP1, the first gate structure GS1, the first source/drain spacer 150, the first source/drain pattern 160, the first back source/drain contact 170, the first front source/drain contact 180, the first front wiring structure 195, and the first back wiring line 50 may be formed in the first region I. The second active pattern AP2, the second gate structure GS2, the second source/drain spacer 250, the second source/drain pattern 260, the second back source/drain contact 270, the second front source/drain contact 280, the second front wiring structure 295, and the second back wiring line 60 may be formed in the second region II.

The first back wiring line 50 may be disposed in a portion of a back interlayer insulating film 290 of the first region I. The second back wiring line 60 may be disposed in a portion of the back interlayer insulating film 290 of the second region II. The first back wiring line 50 and the second back wiring line 60 may each extend in a first direction X. For example, the first back wiring line 50 and the second back wiring line 60 may be a power line that supplies power to the semiconductor device or a signal line that supplies an operating signal of the semiconductor device, respectively.

The first back wiring line 50 may include a first face 50_S1 and a second face 50_S2 that are opposite to each other in a third direction Z. The first face 50_S1 of the first back wiring line 50 may face the first active pattern AP1. The second back wiring line 60 may include a first face 60_S1 and a second face 60_S2 that are opposite to each other in the third direction Z. The second face 60_S2 of the second back wiring line 60 may face the second active pattern AP2. Here, the first direction X may intersect a second direction Y and the third direction Z. Also, the second direction Y may intersect the third direction Z. The terms “upper face,” “lower face,” and “bottom face” may be defined on the basis of the third direction Z. That is, the first face 50_S1 of the first back wiring line 50 may be the upper face of the first back wiring line 50.

The first back wiring line 50 and the second back wiring line 60 are shown to have a trapezoidal cross section, but the embodiment is not limited thereto. Unlike the shown example, the first back wiring line 50 and the second back wiring line 60 may have a rectangular cross section. Taking the first back wiring line 50 as an example, a width of the first face 50_S1 of the first back wiring line 50 in the second direction Y may be smaller than a width of the second face 50_S2 of the first back wiring line 50 in the second direction Y.

For example, the first back wiring line 50 and the second back wiring line 60 may be formed using a damascene process. After a trench extending in the first direction X is formed in the back interlayer insulating film 290, the first back wiring line 50 may be formed by filling the trench with a conductive material.

The first back wiring line 50 and the second back wiring line 60 are shown to have a single conductive film structure, but the embodiment is not limited thereto. Unlike the shown example, each of the first back wiring line 50 and the second back wiring line 60 may have multiple conductive film structures including a wiring barrier film and a wiring filling film. The wiring filling film may fill a trench or a recess defined by the wiring barrier film.

The first back wiring line 50 and the second back wiring line 60 may include, for example, at least one from among a metal, a conductive metal nitride, a conductive metal carbide, a conductive metal oxide, a conductive metal carbonitride, and a two-dimensional material. The two-dimensional (2D) material may include a 2D allotrope or a 2D compound, and may include, for example, but is not limited to, at least one from among graphene, boron nitride (BN), molybdenum sulfide, molybdenum selenide, tungsten sulfide, tungsten selenide, and tantalum sulfide. That is, since the above-mentioned 2D materials are only listed by way of example, the 2D materials that may be included in the semiconductor device of embodiments of the present disclosure are not limited by the above-mentioned materials.

Unlike the shown example, the first back wiring line 50 and the second back wiring line 60 may each extend in the second direction Y. In such a case, the shape of the cross-sectional views taken along the line A1-A1, the line A2-A2, the line B1-B1, the line B2-B2, the line C1-C1, and the line C2-C2 of FIG. 1 may vary.

The back interlayer insulating film 290 may include, for example, at least one from among silicon oxide, silicon nitride, silicon carbonitride, silicon oxynitride, and a low dielectric constant material. The dielectric constant of the low dielectric constant material may have a value smaller than 3.9, which is the dielectric constant of silicon oxide. Although the back interlayer insulating film 290 is shown to be a single film, this is only for convenience of explanation, and the embodiment is not limited thereto.

The first active pattern AP1, the first gate structure GS1, the first source/drain spacer 150, the first source/drain pattern 160, the first back source/drain contact 170, and the first front source/drain contact 180 may be disposed on the first face 50_S1 of the first back wiring line 50. The second active pattern AP2, the second gate structure GS2, the second source/drain spacer 250, the second source/drain pattern 260, the second back source/drain contact 270, and the second front source/drain contact 280 may be disposed on the first face 60_S1 of the second back wiring line 60.

The first active pattern AP1 and the second active pattern AP2 may each extend long in the first direction X. The first active pattern AP1 and the second active pattern AP2 may each be a multi-channel active pattern. For example, the first active pattern AP1 may include a first lower pattern BP1 and a plurality of first sheet patterns NS1. The second active pattern AP2 may include a second lower pattern BP2 and a plurality of second sheet patterns NS2. In the semiconductor device according to some embodiments, the first active pattern AP1 and the second active pattern AP2 may each be an active pattern including a nanosheet or a nanowire.

The first lower pattern BP1 and the second lower pattern BP2 may be disposed on the back interlayer insulating film 290. A part of the back interlayer insulating film 290 may be disposed between the first lower pattern BP1 and the first back wiring line 50, and between the second lower pattern BP2 and the second back wiring line 60.

The first lower pattern BP1 and the second lower pattern BP2 may protrude in the third direction Z. The first lower pattern BP1 and the second lower pattern BP2 may each be a fin-shaped pattern.

The first lower pattern BP1 and the second lower pattern BP2 may each extend long in the first direction X. The first lower pattern BP1 may be spaced apart from the second lower pattern BP2 in the second direction Y. The first lower pattern BP1 and the second lower pattern BP2 may be separated by a fin trench extending in the first direction X.

In some embodiments, the first lower pattern BP1 may come into contact with the back interlayer insulating film 290. The second lower pattern BP2 may come into contact with the back interlayer insulating film 290.

The plurality of first sheet patterns NS1 may be disposed on the first lower pattern BP1. The plurality of first sheet patterns NS1 may be spaced apart from the first lower pattern BP1 in the third direction Z. The first lower pattern BP1 may be disposed between the back interlayer insulating film 290 and the plurality of first sheet patterns NS1.

The plurality of second sheet patterns NS2 may be disposed on the second lower pattern BP2. The plurality of second sheet patterns NS2 may be spaced apart from the second lower pattern BP2 in the third direction Z. The second lower pattern BP2 may be disposed between the back interlayer insulating film 290 and the plurality of second sheet patterns NS2.

Although each of three first sheet patterns NS1 and three second sheet patterns NS2 is shown as being disposed in the third direction Z, this is only for convenience of explanation, and the embodiment is not limited thereto.

The first lower pattern BP1 and the second lower pattern BP2 may each include silicon or germanium, which is an elemental semiconductor material. Alternatively, the first lower pattern BP1 and the second lower pattern BP2 may each include a compound semiconductor, and may include, for example, a group IV-IV compound semiconductor or a group III-V compound semiconductor. The group IV-IV compound semiconductor may include, for example, a binary compound or a ternary compound including at least two or more from among carbon (C), silicon (Si), germanium (Ge) and tin (Sn), or a compound obtained by doping these elements with a group IV element. The group III-V compound semiconductor may be, for example, one from among a binary compound, a ternary compound, and a quaternary compound formed by combining at least one from among aluminum (Al), gallium (Ga) and indium (In) as a group III element with one from among phosphorus (P), arsenic (As), and antimony (Sb) as a group V element.

Each of the first sheet pattern NS1 and the second sheet pattern NS2 may include one from among silicon and germanium which is an elemental semiconductor material, a group IV-IV compound semiconductor, and a group III-V compound semiconductor. A width of the first sheet pattern NS1 in the second direction Y may increase or decrease in proportion to a width of the first lower pattern BP1 in the second direction Y. The width of the second sheet pattern NS2 in the second direction Y may increase or decrease in proportion to the width of the second lower pattern BP2 in the second direction Y.

When taking the first sheet pattern NS1 as an example, although the widths in the second direction Y of each first sheet pattern NS1 disposed on the first lower pattern BP1 are shown as being the same, the embodiment is not limited thereto.

A field insulating film 105 may be disposed on the first back wiring line 50 and the second back wiring line 60. For example, the field insulating film 105 may be disposed on the first face 50_S1 of the first back wiring line 50 and the first face 60_S1 of the second back wiring line 60.

The field insulating film 105 may be disposed on side walls of the first lower pattern BP1 and side walls of the second lower pattern BP2. As an example, the field insulating film 105 may cover the entire side walls of the first lower pattern BP1 and the entire side walls of the second lower pattern BP2. Unlike the shown example, as another example, the field insulating film 105 may cover a part of the side walls of the first lower pattern BP1 and/or a part of the side walls of the second lower pattern BP2.

The field insulating film 105 does not cover the first face (e.g., upper face) of the first lower pattern and the first face (e.g., upper face) of the second lower pattern BP2. On the basis of the first back wiring line 50 and the second back wiring line 60, the first sheet pattern NS1 and the second sheet pattern NS2 are disposed to be higher than the upper face of the field insulating film 105. The field insulating film 105 may include an upper face and a bottom face that are opposite to each other in the third direction Z. The bottom face of the field insulating film 105 faces the first back wiring line 50 and the second back wiring line 60.

The field insulating film 105 may include, for example, an oxide film, a nitride film, an oxynitride film or a combined film thereof. Although the field insulating film 105 is shown as being a single film, this is only for convenience of explanation, and the embodiment is not limited thereto.

The first gate structures GS1 and the second gate structures GS2 may be disposed on the upper face of the field insulating film 105. The first gate structures GS1 and the second gate structures GS2 may extend in the second direction Y, respectively. The first gate structures GS1 may be disposed to be spaced apart in the first direction X. The first gate structures GS1 may be adjacent to each other in the first direction X. The second gate structures GS2 may be disposed to be spaced apart in the first direction X. The second gate structures GS2 may be adjacent to each other in the first direction X.

The first gate structure GS1 may be disposed on the first active pattern AP1. The first gate structure GS1 may intersect the first active pattern AP1. The second gate structure GS2 may be disposed on the second active pattern AP2. The second gate structure GS2 may intersect the second active pattern AP2.

The first gate structure GS1 may be disposed on the first lower pattern BP1. The first gate structure GS1 may surround the first sheet pattern NS1. The second gate structure GS2 may be disposed on the second lower pattern BP2. The second gate structure GS2 may surround the second sheet pattern NS2.

The first gate structure GS1 may include, for example, a first gate electrode 120, a first gate insulating film 130, a first gate spacer 140, and a first gate capping pattern 145. The second gate structure GS2 may include, for example, a second gate electrode 220, a second gate insulating film 230, a second gate spacer 240, and a second gate capping pattern 245.

The first gate structure GS1 may include a plurality of first inner gate structures I_GS1 disposed between the first sheet patterns NS1 adjacent to each other in the third direction Z, and between the first lower pattern BP1 and a lowermost one of the first sheet patterns NS1. The first inner gate structure I_GS1 may be disposed between the first lower pattern BP1 and the bottom face of the lowermost one of the first sheet patterns NS1, and between the upper face and bottom face of adjacent ones of the first sheet patterns NS1 that face each other the third direction Z. The first inner gate structure I_GS1 may include a portion of the first gate electrode 120 and a portion of the first gate insulating film 130. The number of the first inner gate structures I_GS1 may be equal to the number of the first sheet patterns NS1. The first inner gate structures I_GS1 may come into contact with the upper face of the first lower patterns BP1, the upper face of the first sheet patterns NS1, and the bottom face of the first sheet patterns NS1.

The second gate structure GS2 may include a plurality of second inner gate structures I_GS2 disposed between the second sheet patterns NS2 adjacent to each other in the third direction Z, and between the second lower pattern BP2 and a lowermost one of the second sheet patterns NS2. The second inner gate structure I_GS2 may be disposed between the second lower pattern BP2 and the bottom face of the lowermost one of the second sheet pattern NS2, and between the upper face bottom face of adjacent ones of the second two sheet patterns NS2 that face each other in the third direction Z. The second inner gate structure I_GS2 may include a portion of the second gate electrode 220 and a portion of the second gate insulating film 230. The number of the second inner gate structures I_GS2 may be equal to the number of the second sheet patterns NS2. The second inner gate structures I_GS2 may come into contact with the upper face of the second lower patterns BP2, the upper faces of the second sheet patterns NS2, and the bottom face of the second sheet patterns NS2.

In some embodiments, the first inner gate structure I_GS1 may come into contact with the first source/drain pattern 160, and the second inner gate structure I_GS2 may come into contact with the second source/drain pattern 260.

The first gate electrode 120 may be disposed on the first lower pattern BP1. The first gate electrode 120 may intersect the first lower pattern BP1. The first gate electrode 120 may surround the first sheet pattern NS1. The second gate electrode 220 may be disposed on the second lower pattern BP2. The second gate electrode 220 may intersect the second lower pattern BP2. The second gate electrode 220 may surround the second sheet pattern NS2.

In the cross-sectional view such as FIG. 2, the upper face of the first gate electrode 120 and the upper face of the second gate electrode 220 are shown as being a concave curved face, but the embodiment is not limited thereto. For example, the upper faces of the first gate electrode 120 and the second gate electrode 220 may be a plane (e.g., flat).

Each of the first gate electrode 120 and the second gate electrode 220 may include, for example, at least one from among a metal, a conductive metal nitride, a metal silicide, a doped semiconductor material, a conductive metal oxide, a conductive metal silicon oxide, and a conductive metal oxynitride. Each of the first gate electrode 120 and the second gate electrode 220 may include, but is not limited to, for example, at least one from among titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlCN), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (NiPt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and combinations thereof. The conductive metal oxide and conductive metal oxynitride may include, but is not limited to, an oxidized form of the aforementioned materials.

The first gate insulating film 130 extends along the upper face of the field insulating film 105 and the upper face of the first lower pattern BP1 of the first region I. The first gate insulating film 130 may surround a plurality of first sheet patterns NS1. The first gate insulating film 130 may be disposed along the periphery of the first sheet pattern NS1. The first gate electrode 120 may be disposed on the first gate insulating film 130. The first gate insulating film 130 may be disposed between the first gate electrode 120 and the first sheet pattern NS1.

The second gate insulating film 230 may extend along the upper face of the field insulating film 105 and the upper face of the second lower pattern BP2 of the second region II. The second gate insulating film 230 may surround the plurality of second sheet patterns NS2. The second gate insulating film 230 may be disposed along the periphery of the second sheet pattern NS2. The second gate electrode 220 may be disposed on the second gate insulating film 230. The second gate insulating film 230 may be disposed between the second gate electrode 220 and the second sheet pattern NS2.

In some embodiments, the portion of the first gate insulating film 130 included in the first inner gate structure I_GS1 may come into contact with the first source/drain pattern 160, and the portion of the second gate insulating film 230 included in the second inner gate structure I_GS2 may come into contact with the second source/drain pattern 260.

Each of the first gate insulating film 130 and the second gate insulating film 230 may include silicon oxide, silicon oxynitride, silicon nitride, or a high dielectric constant material having a dielectric constant greater than a dielectric constant of silicon oxide. The high dielectric constant material may include, for example, one or more from among boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate.

Although each of the first gate insulating film 130 and the second gate insulating film 230 is shown as being a single film, this is only for convenience of explanation, and the embodiment is not limited thereto. Each of the first gate insulating film 130 and the second gate insulating film 230 may include a plurality of films. For example, the first gate insulating film 130 may include an interfacial film and a high dielectric constant insulating film disposed between the first active pattern AP1 and the first gate electrode 120. For example, the interfacial film may not be formed along the profile of the upper face of the field insulating film 105 in the first region I.

The semiconductor device according to some embodiments may include a negative capacitance (NC) FET that uses a negative capacitor. For example, each of the first gate insulating film 130 and the second gate insulating film 230 may include a gate ferroelectric material film having ferroelectric properties, and a gate paraelectric material film having paraelectric properties.

The gate ferroelectric material film may have a negative capacitance, and the gate paraelectric material film may have a positive capacitance. For example, if two or more capacitors are connected in series and the capacitance of each capacitor has a positive value, the overall capacitances decrease from the capacitance of each of the individual capacitors. On the other hand, if at least one of the capacitances of two or more capacitors connected in series has a negative value, the overall capacitances may be greater than an absolute value of each of the individual capacitances, while having a positive value.

When the gate ferroelectric material film having the negative capacitance and the gate paraelectric material film having the positive capacitance are connected in series, the overall capacitance values of the gate ferroelectric material film and the gate paraelectric material film connected in series may increase. By the use of the increased overall capacitance value, a transistor including the gate ferroelectric material film may have a subthreshold swing (SS) below 60 mV/decade at room temperature.

The gate ferroelectric material film may have ferroelectric properties. The gate ferroelectric material film may include, for example, at least one from among hafnium oxide, hafnium zirconium oxide, barium strontium titanium oxide, barium titanium oxide, and lead zirconium titanium oxide. Here, as an example, the hafnium zirconium oxide may be a material obtained by doping hafnium oxide with zirconium (Zr). As another example, the hafnium zirconium oxide may be a compound of hafnium (Hf), zirconium (Zr), and oxygen (O).

The gate ferroelectric material film may further include a doped dopant. For example, the dopant may include at least one from among aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and tin (Sn). The type of dopant included in the gate ferroelectric material film may vary, depending on which type of ferroelectric material is included in the gate ferroelectric material film.

When the gate ferroelectric material film includes hafnium oxide, the dopant included in the gate ferroelectric material film may include, for example, at least one from among gadolinium (Gd), silicon (Si), zirconium (Zr), aluminum (Al), and yttrium (Y).

When the dopant is aluminum (Al), the gate ferroelectric material film may include 3 to 8 atomic % (at %) aluminum. Here, a ratio of the dopant may be a ratio of aluminum to the sum of hafnium and aluminum.

When the dopant is silicon (Si), the gate ferroelectric material film may include 2 to 10 at % silicon. When the dopant is yttrium (Y), the gate ferroelectric material film may include 2 to 10 at % yttrium. When the dopant is gadolinium (Gd), the gate ferroelectric material film may include 1 to 7 at % gadolinium. When the dopant is zirconium (Zr), the gate ferroelectric material film may include 50 to 80 at % zirconium.

The gate paraelectric material film may have the paraelectric properties. The gate paraelectric material film may include at least one from among, for example, a silicon oxide and a metal oxide having a high dielectric constant. The metal oxide included in the gate paraelectric material film may include, for example, but is not limited to, at least one from among hafnium oxide, zirconium oxide, and aluminum oxide.

The gate ferroelectric material film and the gate paraelectric material film may include the same material as each other. The gate ferroelectric material film has the ferroelectric properties, but the gate paraelectric material film may not have the ferroelectric properties. For example, when the gate ferroelectric material film and the gate paraelectric material film include hafnium oxide, a crystal structure of hafnium oxide included in the gate ferroelectric material film is different from a crystal structure of hafnium oxide included in the gate paraelectric material film. For example, the gate ferroelectric material film may include crystal grains having an orthorhombic crystal structure.

The gate ferroelectric material film may have a thickness having the ferroelectric properties. The thickness of the gate ferroelectric material film may be, for example, but is not limited to, 0.5 to 10 nm. Since a critical thickness that exhibits the ferroelectric properties may vary for each ferroelectric material, the thickness of the gate ferroelectric material film may vary depending on the ferroelectric material.

As an example, the first gate insulating film 130 may include one gate ferroelectric material film. As another example, the first gate insulating film 130 may include a plurality of gate ferroelectric material films spaced apart from each other. The first gate insulating film 130 may have a stacked film structure in which the plurality of gate ferroelectric material films and the plurality of gate paraelectric material films are alternately stacked.

The first gate spacer 140 may be disposed on a side wall of the first gate electrode 120. The first gate spacer 140 may not be disposed between the first lower pattern BP1 and the lowermost one of the first sheet patterns NS1, and between the first sheet patterns NS1 adjacent in the third direction Z. The second gate spacer 240 may be disposed on a side wall of the second gate electrode 220. The second gate spacer 240 may not be disposed between the second lower pattern BP2 and the lowermost one of the second sheet patterns NS2, and between the second sheet patterns NS2 adjacent in the third direction Z.

The first gate spacer 140 and the second gate spacer 240 may each include, for example, at least one from among silicon nitride (SiN), silicon oxynitride (SiON), silicon oxide (SiO₂), silicon oxycarbonitride (SiOCN), silicon boronitride (SiBN), silicon oxyboronitride (SiOBN), silicon oxycarbide (SiOC), and combinations thereof. Although the first gate spacer 140 and the second gate spacer 240 are each shown as being a single film, this example is only for convenience of explanation, and is not limited thereto.

The first gate capping pattern 145 may be disposed on the first gate electrode 120. The second gate capping pattern 245 may be disposed on the second gate electrode 220. The upper face of the first gate capping pattern 145 and the upper face of the second gate capping pattern 245 may be disposed on the same plane as the upper face of a first front interlayer insulating film 190. Unlike the shown example, as an example, the first gate capping pattern 145 may be disposed between a plurality of the first gate spacers 140. As another example, the first gate capping pattern 145 may not be disposed on the first gate electrode 120.

The first gate capping pattern 145 and the second gate capping pattern 245 may include, for example, at least one from among silicon nitride (SiN), silicon oxynitride (SiON), silicon carbonitride (SiCN), silicon oxycarbonitride (SiOCN), and combinations thereof. The first gate capping pattern 145 and the second gate capping pattern 245 may each include a material having an etch selectivity with respect to the first front interlayer insulating film 190.

A first source/drain recess 150R may be formed on at least one side of the first gate electrode 120. The first source/drain recess 150R may be disposed between a plurality of the first gate electrodes 120 adjacent in the first direction X. The first source/drain recess 150R may be formed in the first active pattern AP1. A side wall of the first source/drain recess 150R may be defined by the first sheet patterns NS1 and the first inner gate structures I_GS1. In some embodiments, a bottom face of the first source/drain recess 150R may be defined by the first lower pattern BP1.

The first source/drain spacer 150 may be disposed in the first source/drain recess 150R. The first source/drain spacer 150 may fill a lower part of the first source/drain recess 150R. The first source/drain spacer 150 may extend along a bottom face of the first source/drain recess 150R.

In some embodiments, the first source/drain spacer 150 may come into contact with the first lower pattern BP1.

In some embodiments, the upper face 150US of the first source/drain spacer 150 may be concave toward the first back wiring line 50.

The first source/drain pattern 160 may be disposed in the first source/drain recess 150R. The first source/drain pattern 160 may be disposed on the first source/drain spacer 150. The first source/drain pattern 160 may fill the first source/drain recess 150R. The first source/drain pattern 160 may come into contact with the first active pattern AP1. The first source/drain pattern 160 may come into contact with one or more of the first sheet patterns NS1. The first source/drain spacer 150 may extend along the bottom face of the first source/drain pattern 160.

The first source/drain pattern 160 may include a first back connecting epitaxial pattern 160_1 and a first front connecting epitaxial pattern 160_2. The first back connecting epitaxial pattern 160_1 may be connected to the first back wiring line 50. The first front connecting epitaxial pattern 160_2 may be connected to a first front wiring line 197 of the first front wiring structure 195.

A second source/drain recess 250R may be formed on at least one side of the second gate electrode 220. The second source/drain recess 250R may be disposed between a plurality of the second gate electrodes 220 adjacent to each other in the first direction X. The second source/drain recess 250R may be formed in the second active pattern AP2. The side wall of the second source/drain recess 250R may be defined by the second sheet patterns NS2 and the second inner gate structures I_GS2. In some embodiments, the bottom face of the second source/drain recess 250R may be defined by the second lower pattern BP2.

The second source/drain spacer 250 may be disposed inside the second source/drain recess 250R. The second source/drain spacer 250 may fill the lower part of the second source/drain recess 250R. The second source/drain spacer 250 may extend along the bottom face of the second source/drain recess 250R.

In some embodiments, the second source/drain spacer 250 may come into contact with the second lower pattern BP2.

In some embodiments, the upper face 250US of the second source/drain spacer 250 may be concave toward the second back wiring line 60.

The second source/drain pattern 260 may be disposed inside the second source/drain recess 250R. The second source/drain pattern 260 may be disposed on the second source/drain spacer 250. The second source/drain pattern 260 may fill the second source/drain recess 250R. The second source/drain pattern 260 may come into contact with the second active pattern AP2. The second source/drain pattern 260 may come into contact with one or more of the second sheet patterns NS2. The second source/drain spacer 250 may extend along a bottom face of the second source/drain pattern 260.

The second source/drain pattern 260 may include a second back connecting epitaxial pattern 260_1 and a second front connecting epitaxial pattern 260_2. The second back connecting epitaxial pattern 260_1 may be connected to the second back wiring line 60. The second front connecting epitaxial pattern 260_2 may be connected to a second front wiring line 297 of the second front wiring structure 295.

The first source/drain pattern 160 may be included in a source/drain of a transistor that uses the first sheet patterns NS1 as a channel region. The second source/drain pattern 260 may be included in the source/drain of a transistor that uses the second sheet patterns NS2 as a channel region.

An external shape of the first source/drain pattern 160 and an external shape of the second source/drain pattern 260 are shown as being a shape similar to a hexagon, but are not limited thereto. Unlike those shown, the external shape of the first source/drain pattern 160 and the external shape of the second source/drain pattern 260 may be a shape similar to a pentagon or a rectangle.

In some embodiments, the second source/drain spacer 250 may include a different material from a material of the first source/drain spacer 150. The second source/drain spacer 250 and the first source/drain spacer 150 may have different etch selectivity in the same etching process.

The first source/drain spacer 150 may include a dielectric material. The first source/drain spacer 150 may include, for example, at least one from among silicon nitride (SiN), silicon oxynitride (SiON), silicon oxycarbonitride (SiOCN), silicon boronitride (SiBN), silicon oxyboronitride (SiOBN), silicon oxycarbide (SiOC), and combinations thereof. The second source/drain spacer 250 may include a SiGe-series material. The second source/drain spacer 250 may include at least one from among SiGe, SiGeC, and SiGeB.

The first source/drain pattern 160 and the second source/drain pattern 260 may each include an epitaxial pattern. The first source/drain pattern 160 and the second source/drain pattern 260 may each include a semiconductor material.

The first source/drain pattern 160 and the second source/drain pattern 260 may include, for example, silicon or germanium which is an elemental semiconductor material. Also, the first source/drain pattern 160 and the second source/drain pattern 260 may include, for example, a binary compound or a ternary compound including at least two or more from among carbon (C), silicon (Si), germanium (Ge), and tin (Sn), or a compound obtained by doping these elements with a group IV element. The first source/drain pattern 160 and the second source/drain pattern 260 may each include an epitaxial film made of a semiconductor material. Although the first source/drain pattern 160 and the second source/drain pattern 260 are shown as being a single film, this is only for convenience of explanation and is not limited thereto.

The first source/drain pattern 160 and the second source/drain pattern 260 may include dopants doped into the semiconductor material. The first source/drain pattern 160 may include impurities of a first conductivity type, and the second source/drain pattern 260 may include impurities of a second conductivity type different from the first conductivity type. For example, the first source/drain pattern 160 may include a p-type dopant, and the second source/drain pattern 260 may include an n-type dopant.

The p-type dopant may include, but is not limited to, at least one from among boron (B) and gallium (Ga). The n-type dopant may include, but is not limited to, at least one from among phosphorus (P), arsenic (As), antimony (Sb), and bismuth (Bi).

In some embodiments, a first thickness T1 of the first source/drain spacer 150 may be substantially the same as a second thickness T2 of the second source/drain spacer 250. The first thickness T1 and the second thickness T2 may be defined on the basis of the third direction Z. For example, the first thickness T1 and the second thickness T2 may be a minimum thickness of the first source/drain spacer 150 and the second source/drain spacer 250, respectively.

The first front interlayer insulating film 190 may be disposed on the first lower pattern BP1, the second lower pattern BP2, and the field insulating film 105. The first front interlayer insulating film 190 may be disposed on the first source/drain pattern 160 and the second source/drain pattern 260. The first front interlayer insulating film 190 may not cover the upper face of the first gate capping pattern 145 and the upper face of the second gate capping pattern 245. For example, the upper face of the first front interlayer insulating film 190 may be disposed in the same plane as the upper face of the first gate capping pattern 145.

The first front interlayer insulating film 190 may include, for example, at least one from among silicon oxide, silicon nitride, silicon oxynitride, and a low dielectric constant material. The low dielectric constant material may include, for example, but is not limited to, at least one from among Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethyleyCloTetraSiloxane (OMCTS), HexaMethylDiSiloxane (HMDS), TriMethylSilyl Borate (TMSB), DiAcetoxyDitertiaryButoSiloxane (DADBS), TriMethylSilil Phosphate (TMSP), PolyTetraFluoroEthylene (PTFE), Tonen SilaZen (TOSZ), Fluoride Silicate Glass (FSG), polyimide nanofoams such as polypropylene oxide, Carbon Doped Silicon Oxide (CDO), Organo Silicate Glass (OSG), SILK, Amorphous Fluorinated Carbon, silica aerogels, silica xerogels, mesoporous silica, and combinations thereof.

A source/drain etching stop film 185 may extend along the profile of the first source/drain pattern 160. The source/drain etching stop film 185 may be disposed between the first source/drain pattern 160 and the first front interlayer insulating film 190. The source/drain etching stop film 185 may extend along the profile of the second source/drain pattern 260. The source/drain etching stop film 185 may be disposed between the second source/drain pattern 260 and the first front interlayer insulating film 190. The source/drain etching stop film 185 may include, for example, at least one from among silicon nitride (SiN), silicon oxynitride (SiON), silicon oxycarbonitride (SiOCN), silicon boronitride (SiBN), silicon oxyboronitride (SiOBN), silicon oxycarbide (SiOC), and combinations thereof.

The first back source/drain contact 170 may extend long in the third direction Z. The first back source/drain contact 170 may be connected to the first source/drain pattern 160. For example, the first back source/drain contact 170 may be connected to the first back connecting epitaxial pattern 160_1. The first back source/drain contact 170 may be electrically connected to the first source/drain pattern 160.

The first back source/drain contact 170 may be disposed between the first source/drain pattern 160 and the first back wiring line 50. The first back source/drain contact 170 may connect the first source/drain pattern 160 and the first back wiring line 50. The first back source/drain contact 170 may be connected to the first back wiring line 50. The first back source/drain contact 170 may be connected to the first face 50_S1 of the first back wiring line 50. The first back source/drain contact 170 may extend from the first face 50_S1 of the first back wiring line 50 to the first source/drain pattern 160. A part of the first back source/drain contact 170 may be disposed inside the back interlayer insulating film 290, the first lower pattern BP1, and the first source/drain spacer 150.

The second back source/drain contact 270 may extend long in the third direction Z. The second back source/drain contact 270 may be connected to the second source/drain pattern 260. For example, the second back source/drain contact 270 may be connected to the second back connecting epitaxial pattern 260_1. The second back source/drain contact 270 may be electrically connected to the second source/drain pattern 260.

The second back source/drain contact 270 may be disposed between the second source/drain pattern 260 and the second back wiring line 60. The second back source/drain contact 270 may connect the second source/drain pattern 260 and the second back wiring line 60. The second back source/drain contact 270 may be connected to the second back wiring line 60. The second back source/drain contact 270 may be connected to the first face 60_S1 of the second back wiring line 60. The second back source/drain contact 270 may extend from the first face 60_S1 of the second back wiring line 60 to the second source/drain pattern 260. A part of the second back source/drain contact 270 may be disposed inside the back interlayer insulating film 290, the second lower pattern BP2, and the second source/drain spacer 250.

The upper face 170US of the first back source/drain contact 170 may be disposed inside the first source/drain pattern 160. The upper face 270US of the second back source/drain contact 270 may be disposed inside the second source/drain pattern 260.

In some embodiments, the upper face 170US of the first back source/drain contact 170 and the upper face 270US of the second back source/drain contact 270 may be flat.

In some embodiments, the upper face 170US of the first back source/drain contact 170 and the upper face 270US of the second back source/drain contact 270 may be disposed on the same plane.

A first back contact silicide film 162 may be disposed between the first back source/drain contact 170 and the first source/drain pattern 160. The first back contact silicide film 162 may come into contact with the first back source/drain contact 170. The first back contact silicide film 162 may include a metal silicide material. A second back contact silicide film 262 may be disposed between the second back source/drain contact 270 and the second source/drain pattern 260. The second back contact silicide film 262 may come into contact with the second back source/drain contact 270. The second back contact silicide film 262 may include a metal silicide material.

The first front source/drain contact 180 may extend in the third direction Z. The first front source/drain contact 180 may be connected to the first source/drain pattern 160. For example, the first front source/drain contact 180 may be connected to the first front connecting epitaxial pattern 160_2. The first front source/drain contact 180 may be electrically connected to the first source/drain pattern 160.

The first source/drain pattern 160 may be disposed between the first front source/drain contact 180 and the first back wiring line 50. The first front source/drain contact 180 may be disposed inside the first front interlayer insulating film 190 and the first source/drain pattern 160. A part of the first front source/drain contact 180 may be disposed inside the first source/drain pattern 160. The first front source/drain contact 180 may not penetrate the first lower pattern BP1.

The first front source/drain contact 180 may extend in the third direction Z. The first front source/drain contact 180 may be connected to the first source/drain pattern 160. For example, the first front source/drain contact 180 may be connected to the first front connecting epitaxial pattern 160_2. The first front source/drain contact 180 may be electrically connected to the first source/drain pattern 160. An upper face of the first front source/drain contact 180 may be disposed on the same plane as an upper face of the first gate capping pattern 145.

The second source/drain pattern 260 may be disposed between the second front source/drain contact 280 and the second back wiring line 60. The second front source/drain contact 280 may be disposed inside the first front interlayer insulating film 190 and the second source/drain pattern 260. A part of the second front source/drain contact 280 may be disposed inside the second source/drain pattern 260. The second front source/drain contact 280 may not penetrate the second lower pattern BP2.

The second front source/drain contact 280 may extend in the third direction Z. The second front source/drain contact 280 may be connected to the second source/drain pattern 260. For example, the second front source/drain contact 280 may be connected to the second front connecting epitaxial pattern 260_2. The second front source/drain contact 280 may be electrically connected to the second source/drain pattern 260. The upper face of the second front source/drain contact 280 may be disposed on the same plane as the upper face of the second gate capping pattern 245.

A first front contact silicide film 164 may be disposed between the first front source/drain contact 180 and the first source/drain pattern 160. The first front contact silicide film 164 may come into contact with the first front source/drain contact 180. The first front contact silicide film 164 may include a metal silicide material. A second front contact silicide film 264 may be disposed between the second front source/drain contact 280 and the second source/drain pattern 260. The second front contact silicide film 264 may come into contact with the second front source/drain contact 280. The second front contact silicide film 264 may include a metal silicide material.

Each of the first front source/drain contact 180 and the second front source/drain contact 280 is shown to have a single conductive film structure, but the embodiment is not limited thereto. Unlike the shown example, the first front source/drain contacts 180 and the second front source/drain contact 280 may each have multiple conductive film structures including a contact barrier film and a contact filling film. The first front source/drain contact 180 and the second front source/drain contact 280 may each include, for example, at least one from among a metal, a conductive metal nitride, a conductive metal carbide, a conductive metal oxide, a conductive metal carbonitride, and a two-dimensional material.

The second front interlayer insulating film 191 may be disposed on the first front interlayer insulating film 190, the first gate structure GS1, the second gate structure GS2, the first front source/drain contact 180, and the second front source/drain contact 280. The second front interlayer insulating film 191 may include at least one from among, for example, silicon oxide, silicon nitride, silicon carbonitride, silicon oxynitride, and a low dielectric constant material.

The first front wiring structure 195 and the second front wiring structure 295 may be disposed inside the second front interlayer insulating film 191. The first front wiring structure 195 may include a first front via plug 196 and a first front wiring line 197. The second front wiring structure 295 may include a second front via plug 296 and a second front wiring line 297.

The first front wiring structure 195 may be connected to the first front source/drain contact 180. The first front wiring structure 195 may be connected to an upper face of the first front source/drain contact 180. The second front wiring structure 295 may be connected to the second front source/drain contact 280. The second front wiring structure 295 may be connected to an upper face of the second front source/drain contact 280.

The first front source/drain contact 180 may be disposed between the first front wiring structure 195 and the first source/drain pattern 160. The first front source/drain contact 180 may connect the first front wiring structure 195 and the first source/drain pattern 160. The first front source/drain contact 180 may be connected to the first front wiring line 197. For example, the first front wiring structure 195 may not be connected to the first source/drain pattern 160_1 connected to the first back source/drain contact 170. Unlike the shown example, the first front wiring structure 195 may be connected to the first back connecting epitaxial pattern 160_1 through another front source/drain contact. For example, the first front wiring structure 195 may be connected to the first back source/drain contact 170 via the first back connecting epitaxial pattern 160_1.

The second front source/drain contact 280 may be disposed between the second front wiring structure 295 and the second source/drain pattern 260. The second front source/drain contact 280 may connect the second front wiring structure 295 and the second source/drain pattern 260. The second front source/drain contact 280 may be connected to the second front wiring line 297. For example, the second front wiring structure 295 may not be connected to the second source/drain pattern 260_1 connected to the second back source/drain contact 270. Unlike the shown example, the second front wiring structure 295 may be connected to the second back connecting epitaxial pattern 260_1 through another front source/drain contact. For example, the second front wiring structure 295 may be connected to the second back source/drain contact 270 via the second back connecting epitaxial pattern 260_1.

The first front via plug 196, the second via plug 296, the first front wiring line 197, and the second front wiring line 297 may each include at least one from among, for example, a metal, a conductive metal nitride, a conductive metal carbide, a conductive metal oxide, a conductive metal carbonitride, and a two-dimensional material. Although each of the first front via plug 196, the second via plug 296, the first front wiring line 197, and the second front wiring line 297 is shown as being a single conductive film structure, this is only for convenience of explanation, and the embodiment is not limited thereto. Unlike the shown example, as an example, at least one from among the first front via plug 196, the second via plug 296, the first front wiring line 197, and the second front wiring line 297 may have multiple conductive film structures. As another example, each of the first front wiring structure 195 and the second front wiring structure 295 may have an integral structure which has no an interfacial division between each of the first front via plug 196, the second via plug 296, the first front wiring line 197, and the second front wiring line 297.

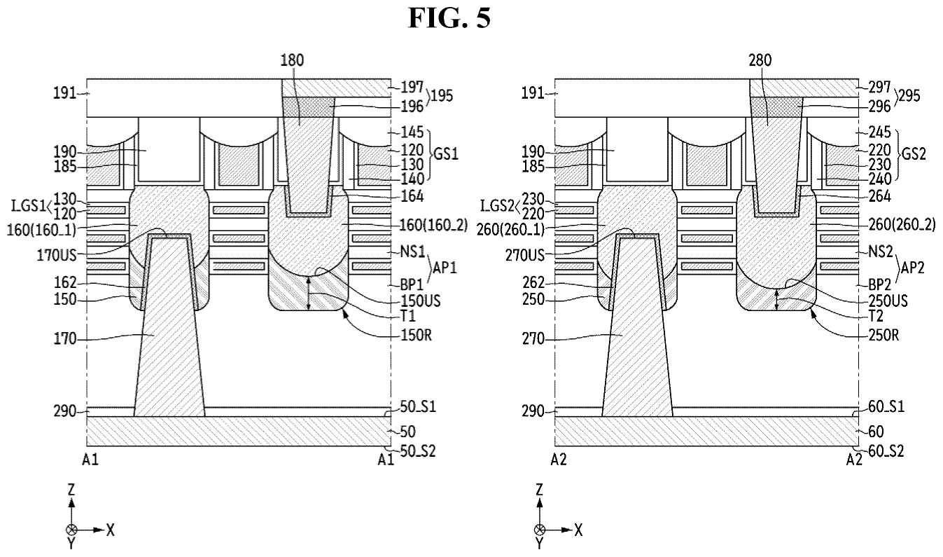

FIGS. 5 to 12 are diagrams for explaining a semiconductor device according to some embodiments. For convenience of explanation, differences from aspects explained with reference to FIGS. 1 to 4 may be mainly explained.

Referring to FIG. 5, in the semiconductor device according to some embodiments, the first thickness T1 of the first source/drain spacer 150 may be different from the second thickness T2 of the second source/drain spacer 250.

For example, the first thickness T1 and the second thickness T2 may be the minimum thickness of the first source/drain spacer 150 and the second source/drain spacer 250, respectively. For example, the first thickness T1 may be greater than the second thickness T2.

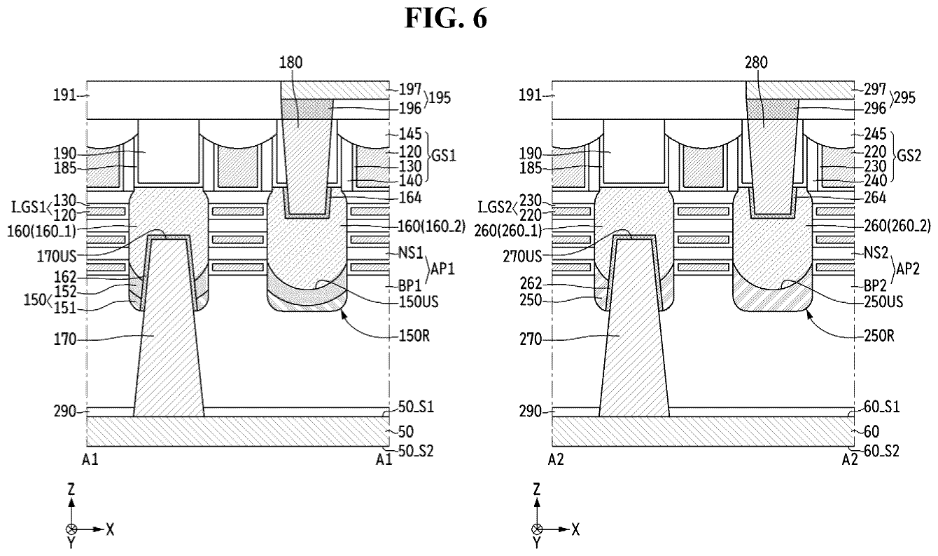

Referring to FIG. 6, in the semiconductor device according to some embodiments, at least one from among the first source/drain spacer 150 and the second source/drain spacer 250 may include a plurality of films.

For example, the first source/drain spacer 150 may include a first spacer 151 and a second spacer 152. The first spacer 151 may extend along the bottom face of the first source/drain recess 150R. The second spacer 152 may extend along the first spacer 151. The first source/drain pattern 160 may fill the first source/drain recess 150R on the second spacer 152. The thickness of the first spacer 151 and the thickness of the second spacer 152 may be set in various ways depending on the material of the first spacer 151, the material of the second spacer 152, and the like.

The first spacer 151 and the second spacer 152 may each include a dielectric material. Each of the first spacer 151 and the second spacer 152 may include, for example, at least one from among silicon nitride (SiN), silicon oxynitride (SiON), silicon oxycarbonitride (SiOCN), silicon boronitride (SiBN), silicon oxyboronitride (SiOBN), silicon oxycarbide (SiOC), and combinations thereof.

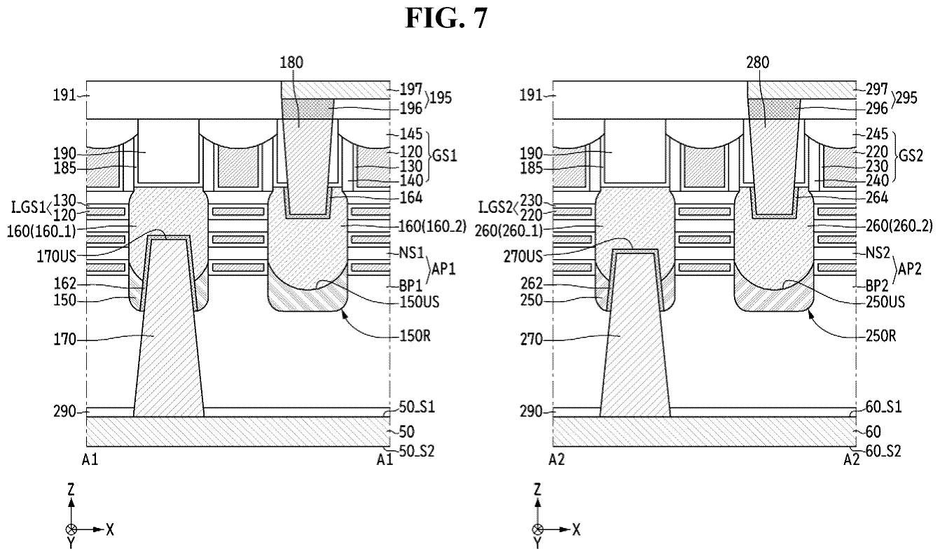

Referring to FIG. 7, in the semiconductor device according to some embodiments, the upper face 170US of the first back source/drain contact 170 and the upper face 270US of the second back source/drain contact 270 may be disposed on different planes from each other.

For example, the upper face 170US of the first back source/drain contact 170 may be disposed above the upper face 270US of the second back source/drain contact 270. The positions of the upper face 170US of the first back source/drain contact 170 and the upper face 270US of the second back source/drain contact 270 may be set in various ways depending on the material of the first spacer 151, the thickness of the first spacer 151, the material of the second spacer 152, the thickness of the second spacer 152, and the like.

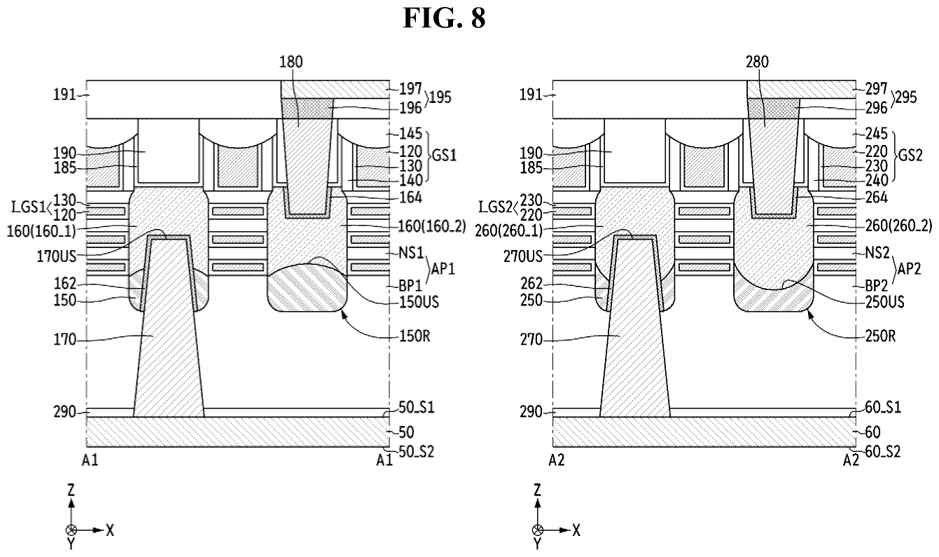

Referring to FIG. 8, in the semiconductor device according to some embodiments, the upper face of at least one from among the first source/drain spacer 150 and the second source/drain spacer 250 may be convex toward the second front interlayer insulating film 191.

For example, the upper face 150US of the first source/drain spacer 150 may be convex toward the second front interlayer insulating film 191.

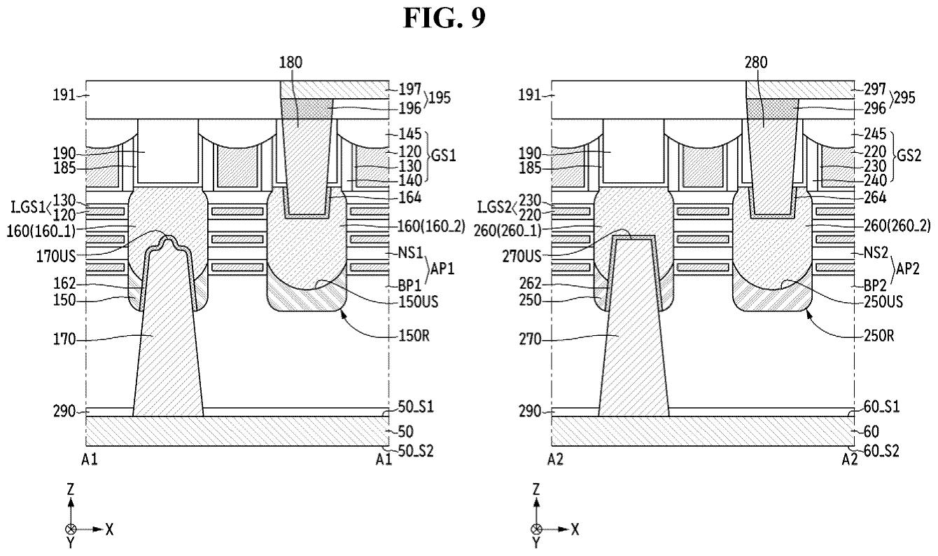

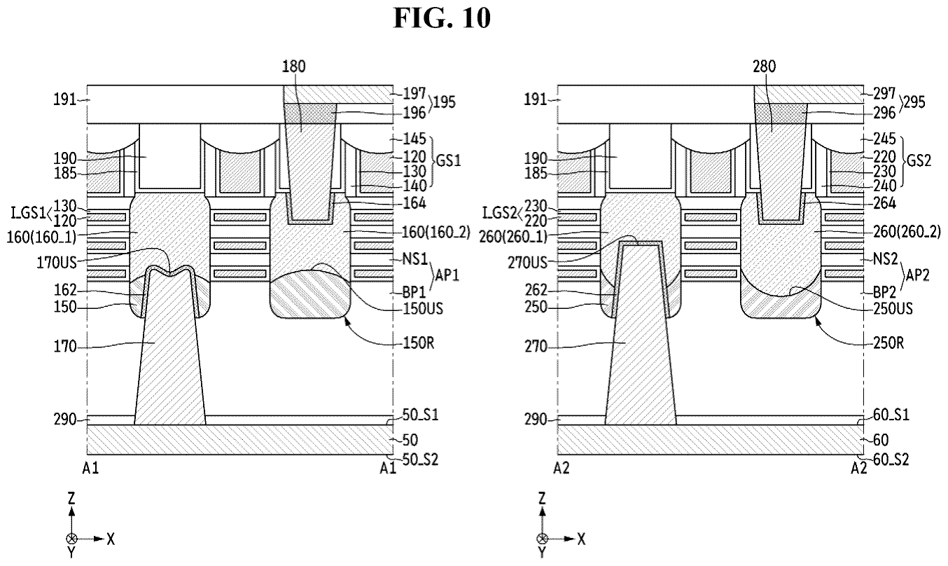

Referring to FIGS. 9 and 10, in the semiconductor device according to some embodiments, the upper face of at least one from the first back source/drain contact 170 and the second back source/drain contact 270 may have a step. The upper face of at least one from among the first back source/drain contact 170 and the second back source/drain contact 270 may have a wavy shape.

For example, the upper face 170US of the first back source/drain contact 170 may include a portion that is convex toward the second front interlayer insulating film 191, and a portion which is concave toward the first back wiring line 50.

For example, referring to FIG. 9, the center portion of the upper face 170US of the first back source/drain contact 170 may be convex toward the second front interlayer insulating film 191, and outer portions of the upper face 170US may be concave toward the first back wiring line 50.

For example, referring to FIG. 10, the center portion of the upper face 170US of the first back source/drain contact 170 may be concave toward the first back wiring line 50, and outer portions of the upper face 170US may be convex toward the second front interlayer insulating film 191.

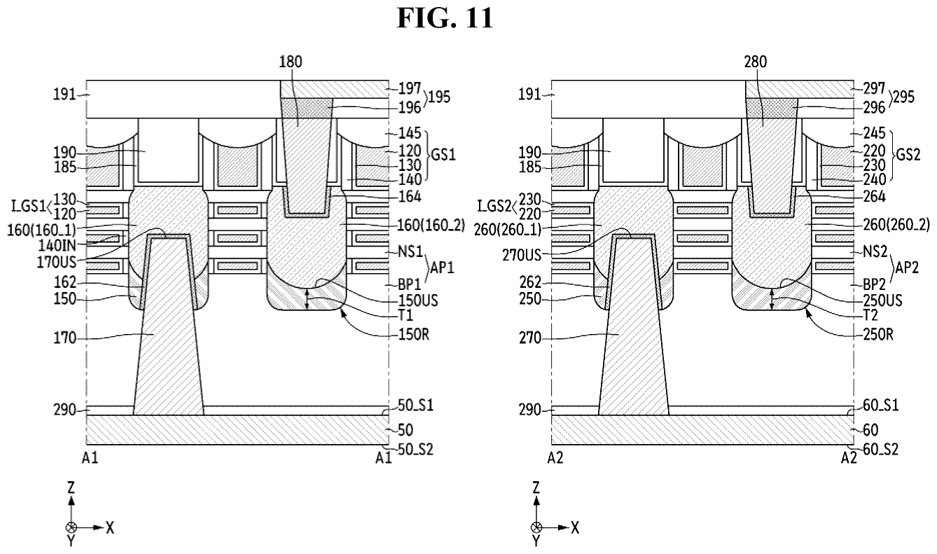

Referring to FIG. 11, in the semiconductor device according to some embodiments, an internal spacer 140IN may be further disposed between the first inner gate structure I_GS1 and the first source/drain pattern 160, and/or between the second inner gate structure I_GS2 and the second source/drain pattern 260.

For example, the internal spacer 140IN may be disposed between the first inner gate structure I_GS1 and the first source/drain pattern 160. The internal spacer 140IN may be disposed between the first sheet patterns NS1 and the first source/drain pattern 160. The internal spacer 140IN may come into contact with the first source/drain pattern 160. The internal spacer 140IN may include an insulating material.

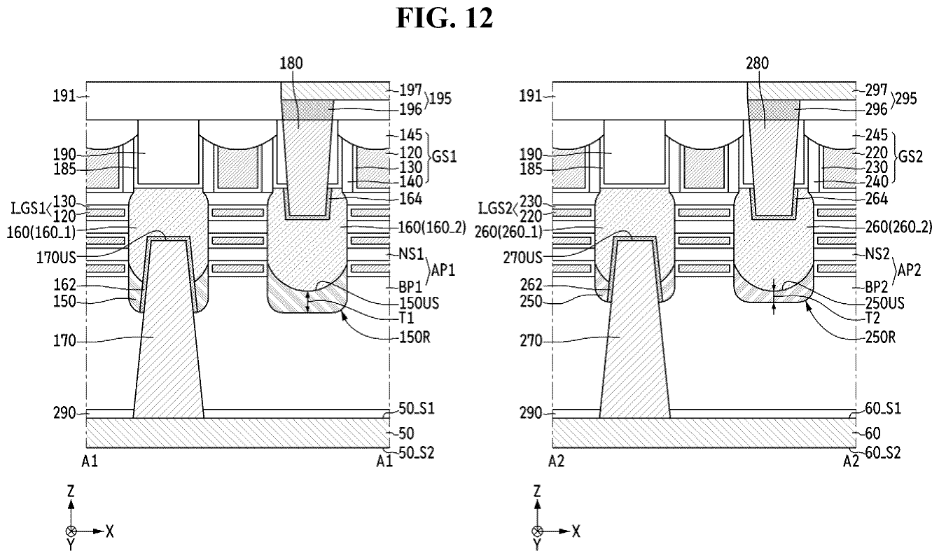

Referring to FIG. 12, in the semiconductor device according to some embodiments, the first source/drain spacer 150 and the second source/drain spacer 250 may include the same material as each other. The first thickness T1 of the first source/drain spacer 150 may be different from the second thickness T2 of the second source/drain spacer 250. For example, the first thickness T1 may be greater than the second thickness T2.

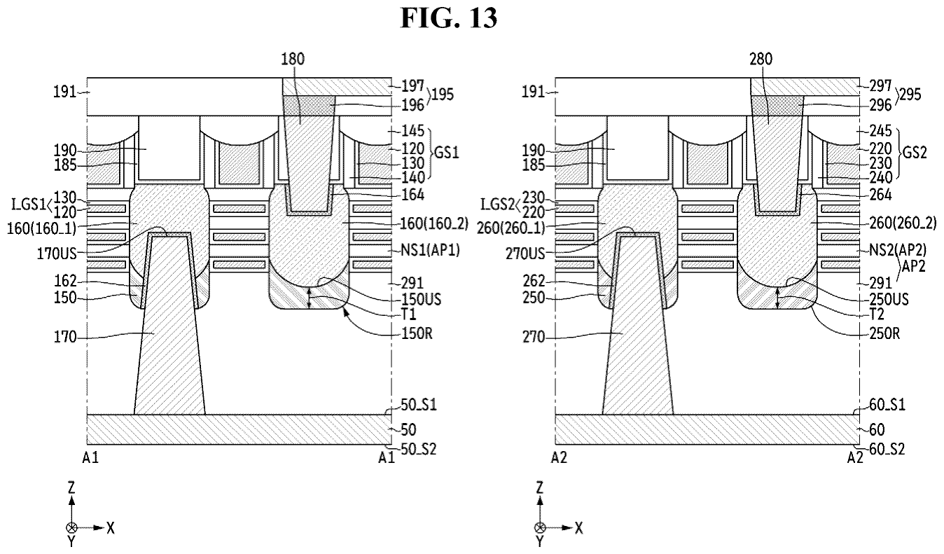

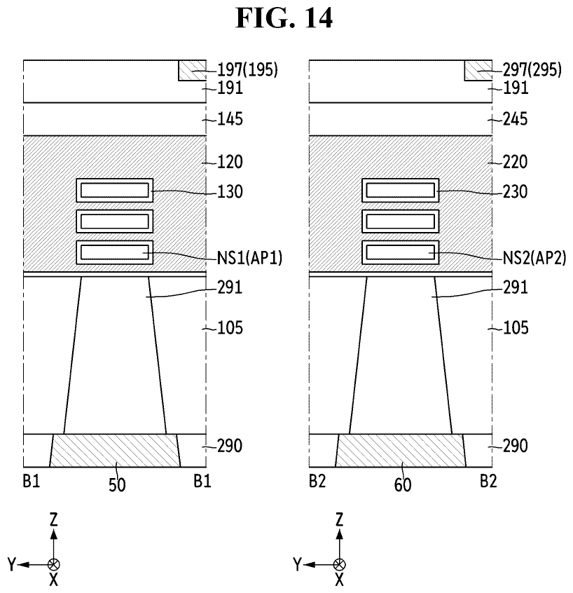

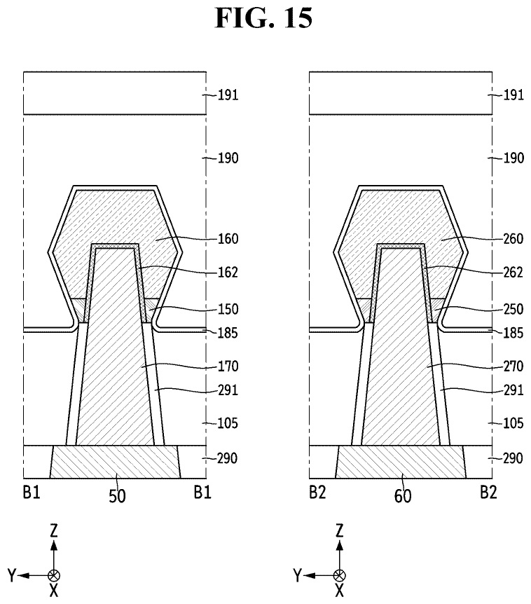

FIGS. 13 to 15 are diagrams for explaining a semiconductor device according to some embodiments. For convenience of explanation, differences from aspects explained with reference to FIGS. 1 to 4 may be mainly explained.

Referring to FIGS. 13 to 15, in the semiconductor device according to some embodiments, the first active pattern AP1 may include only the first sheet pattern NS1. The second active pattern AP2 may include only the second sheet pattern NS2. That is, the first active pattern AP1 may not include the first lower pattern BP1 (see FIG. 2). The second active pattern AP2 may not include the second lower pattern BP2 (see FIG. 2).

A back insertion insulating film 291 may be disposed on the back interlayer insulating film 290. The first active pattern AP1, the first gate structure GS1, the second active pattern AP2, and the second gate structure GS2 may be disposed on the back insertion insulating film 291. The back insertion insulating film 291 may be disposed between the first source/drain pattern 160 and the first back wiring line 50, and between the second source/drain pattern 260 and the second back wiring line 60. A bottom face of the first source/drain recess 150R and a bottom face of the second source/drain recess 250R may be defined by the back insertion insulating film 291. The first source/drain spacer 150 may be disposed between the first source/drain pattern 160 and the first back wiring line 50, and the second source/drain spacer 250 may be disposed between the second source/drain pattern 260 and the second back wiring line 60. The first source/drain spacer 150 and the second source/drain spacer 250 may come into contact with the back insertion insulating film 291.

The first back source/drain contact 170 and the second back source/drain contact 270 may be disposed inside the back insertion insulating film 291. The back insertion insulating film 291 may surround the first back source/drain contact 170 and the second back source/drain contact 270. The back insertion insulating film 291 may cover side walls of the first back source/drain contact 170 and the second back source/drain contact 270.

The back insertion insulating film 291 may be formed by filling a space from which the first lower pattern BP1 and the second lower pattern BP2 are removed with an insulating material. The back insertion insulating film 291 may include an insulating material. The back insertion insulating film 291 may include, for example, an oxide film, a dielectric film, or a combined film thereof. When the back insertion insulating film 291 includes the same material as the field insulating film 105, a boundary between the back insertion insulating film 291 and the field insulating film 105 may not be distinguished.

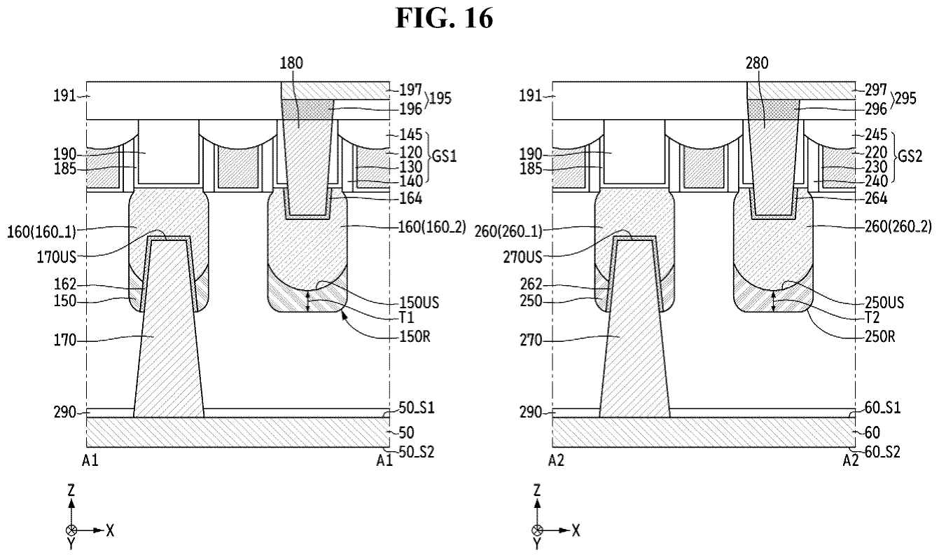

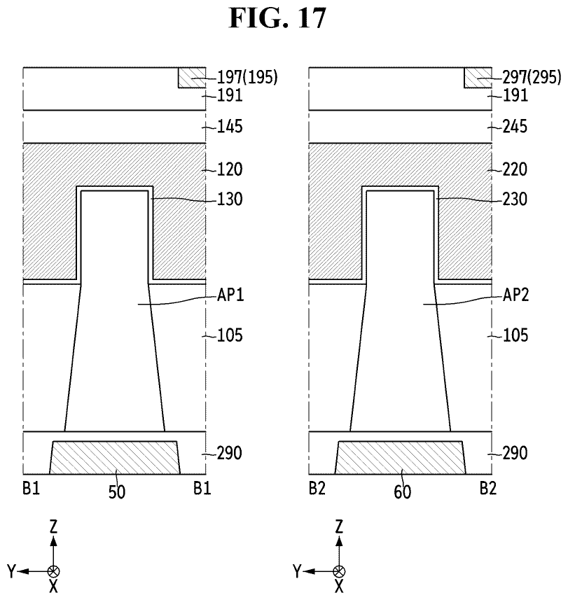

FIGS. 16 and 17 are diagrams for explaining a semiconductor device according to some embodiments. For convenience of explanation, differences from aspects explained with reference FIGS. 1 to 4 may be mainly explained.

Referring to FIGS. 16 and 17, in the semiconductor device according to some embodiments, the first active pattern AP1 may not include the first sheet pattern NS1 (see FIG. 2). The second active pattern AP2 may not include the second sheet pattern NS2 (see FIG. 2). The first inner gate structure I_GS1 (see FIG. 2) may not be disposed between portions of the first source/drain pattern 160 (e.g., the first back connecting epitaxial pattern 160_1 and the first front connecting epitaxial pattern 160_2) adjacent to each other in the first direction X. The second inner gate structure I_GS2 (see FIG. 2) may not be disposed between portions of the second source/drain pattern 260 (e.g., the second back connecting epitaxial pattern 260_1 and the second front connecting epitaxial pattern 260_2) adjacent to each other in the first direction X.

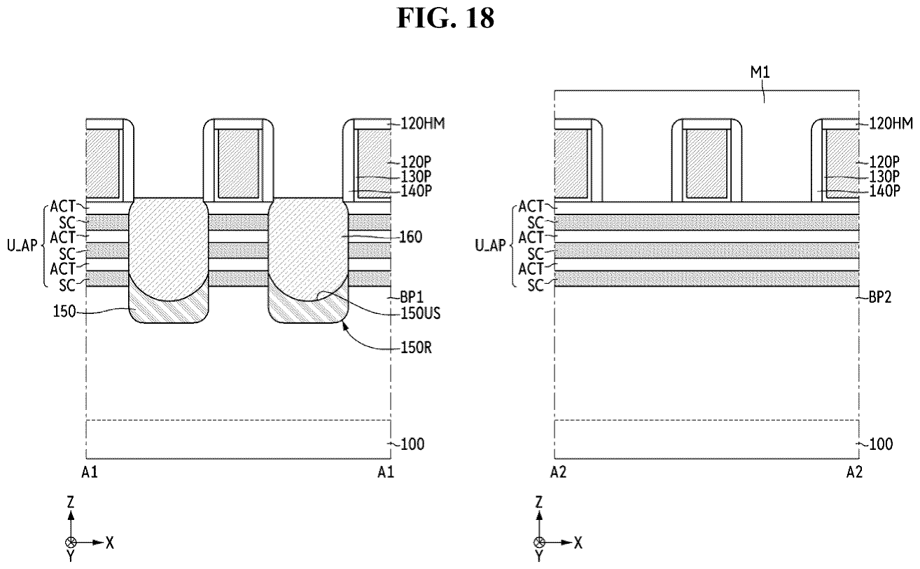

FIGS. 18 to 21 are intermediate stage diagrams for explaining a method for fabricating a semiconductor device according to some embodiments.

Referring to FIG. 18, lower patterns (e.g., a first lower pattern BP1 and a second lower pattern BP2) and an upper pattern structure U_AP may be formed on a substrate 100.

The substrate 100 may be bulk silicon or silicon-on-insulator (SOI). In contrast, the substrate 100 may be a silicon substrate or may include other materials such as, for example, but is not limited to, silicon germanium, silicon germanium-on-insulator (SGOI), indium antimonide, lead telluride, indium arsenide, indium phosphide, gallium arsenide, or gallium antimonide.

The first lower pattern BP1 may be formed on a first region I of the substrate 100. The second lower pattern BP2 may be formed on a second region II of the substrate 100. The upper pattern structure U_AP may be formed on the lower patterns (e.g., the first lower pattern BP1 and the second lower pattern BP2). The upper pattern structure U_AP may include a plurality of sacrificial patterns SC and active patterns ACT that are alternately stacked on the lower patterns (e.g., the first lower pattern BP1 and the second lower pattern BP2). For example, the active patterns ACT may include a silicon film, and the sacrificial patterns SC may include a silicon-germanium film.

Next, a dummy gate insulating film 130p, a dummy gate electrode 120p, and a dummy gate capping film 120HM may be formed on the upper pattern structure U_AP. The dummy gate insulating film 130p may include, for example, but is not limited to, silicon oxide. The dummy gate electrode 120p may include, for example, but is not limited to, polysilicon. The dummy gate capping film 120HM may include, for example, but is not limited to, silicon nitride. A pre-gate spacer 140p may be formed on a side wall of the dummy gate electrode 120p.

Next, a first mask layer M1 that covers the second region II may be formed.

Next, a first source/drain recess 150R may be formed inside the upper pattern structure U_AP of the first region I, by using the dummy gate electrode 120p as a mask. A part of the first source/drain recess 150R may be formed inside the first lower pattern BP1. A lower portion of the first source/drain recess 150R may be defined by the first lower pattern BP1.

The first source/drain spacer 150 may then be formed. The first source/drain spacer 150 may be formed along a part of the first source/drain recess 150R. The first source/drain spacer 150 may extend along a bottom face of the first source/drain recess 150R.

In some embodiments, the first source/drain spacer 150 may be formed by a chemical vapor deposition (CVD) method. For example, the first source/drain spacer 150 may conformally extend along the bottom face of the first source/drain recess 150R.

In some embodiments, the first source/drain spacer 150 may be formed by an epitaxial growth method, by using the substrate 100 as a seed. The first source/drain spacer 150 may extend from the substrate 100 exposed by the bottom face of the first source/drain recess 150R and the substrate 100 exposed by the side face of the first source/drain recess 150R.

The shape of the upper face 150US of the first source/drain spacer 150 may be determined, depending on a first rate at which the first source/drain spacer 150 grows from a portion of the substrate 100 exposed by the bottom face of the first source/drain recess 150R, and a second rate at which the first source/drain spacer 150 grows from a portion of the substrate 100 exposed by the side face of the first source/drain recess 150R.

For example, the second rate may be faster than the first rate. In this case, the thickness of a portion of the first source/drain spacer 150 grown from the portion of the substrate 100 exposed by the side of the first source/drain recess 150R may be greater than the thickness of a portion of the first source/drain spacer 150 grown from the portion of the substrate 100 exposed by the bottom face of the first source/drain recess 150R. In this case, as shown in FIG. 18, the upper face 150US of the first source/drain spacer 150 may have a concave shape toward the substrate 100.

Next, a first source/drain pattern 160 that fills the first source/drain recess 150R may be formed on the first source/drain spacer 150.

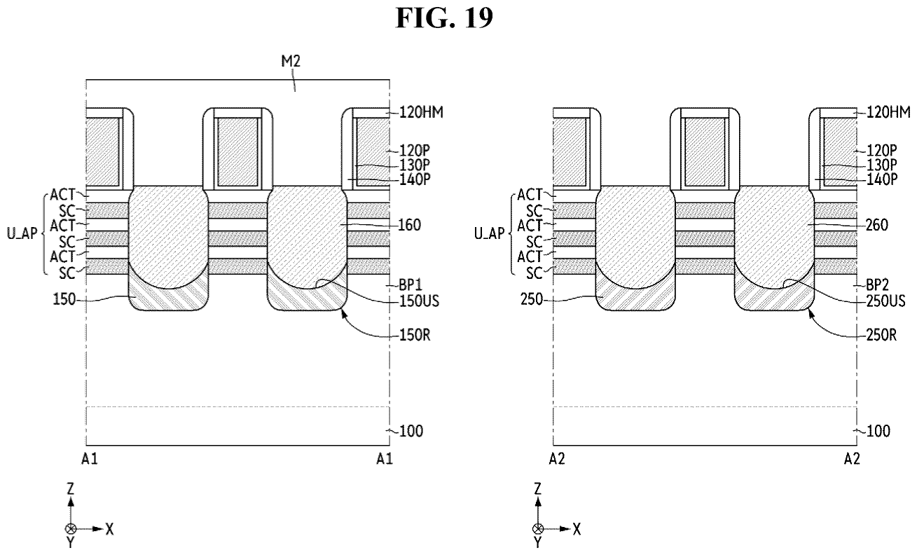

Referring to FIG. 19, a second mask layer M2 that covers the first region I may be formed. The first mask layer M1 may be removed. The second region II may be opened.

Next, a second source/drain recess 250R may be formed in the upper pattern structure U_AP of the second region II, by using the dummy gate electrode 120p as a mask. A part of the second source/drain recess 250R may be formed in the second lower pattern BP2. A lower portion of the second source/drain recess 250R may be defined by the second lower pattern BP2.

The second source/drain spacer 250 may then be formed. The second source/drain spacer 250 may be formed along a part of the second source/drain recess 250R. The second source/drain spacer 250 may extend along a bottom face of the second source/drain recess 250R. A method for forming the second source/drain spacer 250 may be substantially the same as the method for forming the first source/drain spacer 150 described with reference to FIG. 18. The shape of the upper face 250US of the second source/drain spacer 250 may be determined depending on the method for forming the second source/drain spacer 250.

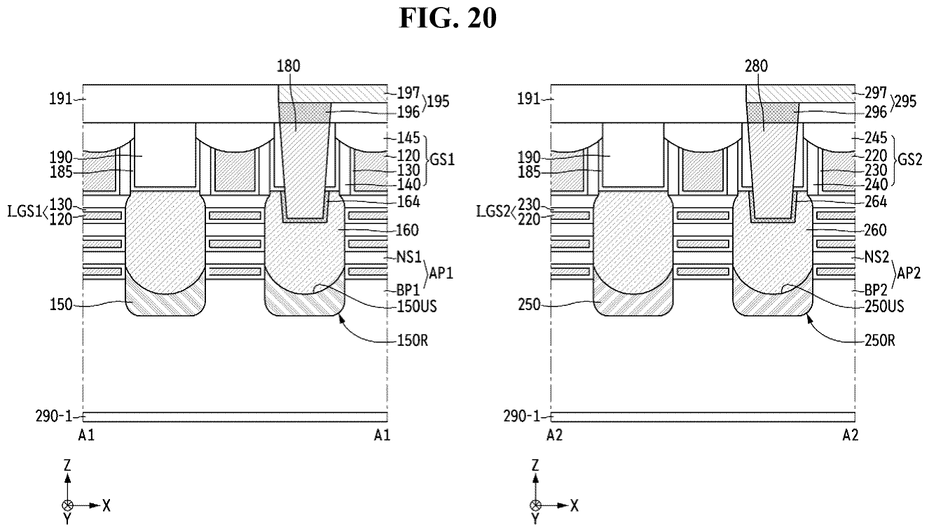

Referring to FIG. 20, the second mask layer M2 may be removed. The first region I may be opened. The source/drain etching stop film 185 and the first front interlayer insulating film 190 may be sequentially formed on the first source/drain pattern 160 and the second source/drain pattern 260.

Next, a part of the first front interlayer insulating film 190, a part of the source/drain etching stop film 185, and the dummy gate capping layer 120HM may be removed to expose the upper face of the dummy gate electrode 120p. While the upper face of the dummy gate electrode 120p is being exposed, the first gate spacer 140 and the second gate spacer 240 may be formed. The dummy gate insulating film 130p and the dummy gate electrode 120p may be removed to expose the upper pattern structure U_AP between the first gate spacers 140 and the upper pattern structure U_AP between the second gate spacers 240.

Next, the sacrificial pattern SC of the first region I may be removed to form the first sheet pattern NS1. The first sheet pattern NS1 may be connected to the first source/drain pattern 160. As a result, the first active pattern AP1 including the first lower pattern BP1 and the first sheet pattern NS1 is formed. The sacrificial pattern SC of the second region II may be removed to form the second sheet pattern NS2. The second sheet pattern NS2 may be connected to the second source/drain pattern 260. As a result, the second active pattern AP2 including the second lower pattern BP2 and the second sheet pattern NS2 may be formed. In addition, the sacrificial pattern SC of the first region I may be removed to form the first gate trench between the first gate spacers 140. When the sacrificial pattern SC of the first region I is removed, a part of the first source/drain pattern 160 may be exposed. The first gate insulating film 130 and the first gate electrode 120 may be formed inside the first gate trench. In addition, the first gate capping pattern 145 may be formed. The sacrificial pattern SC of the second region II may be removed to form the second gate trench between the second gate spacers 240. When the sacrificial pattern SC of the second region II is removed, a part of the second source/drain pattern 260 may be exposed. The second gate insulating film 230 and the second gate electrode 220 may be formed in the second gate trench. Further, the second gate capping pattern 245 may be formed.

Next, the first front source/drain contact 180 may be formed on the first source/drain pattern 160. The second front source/drain contact 280 may be formed on the second source/drain pattern 260.

Next, the second front interlayer insulating film 191 may be formed on the first front interlayer insulating film 190, the first front source/drain contact 180, and the second front source/drain contact 280. The first front wiring structure 195 and the second front wiring structure 295 may be formed inside the second front interlayer insulating film 191.

Next, the substrate 100 may be removed. The first lower pattern BP1 and the second lower pattern BP2 may be exposed by removing the substrate 100. The field insulating film 105 may also be exposed.

Next, a first back interlayer insulating film 290_1 may be formed on the first lower pattern BP1 and the second lower pattern BP2. Unlike the shown example, the first back interlayer insulating film 290_1 may not be formed.

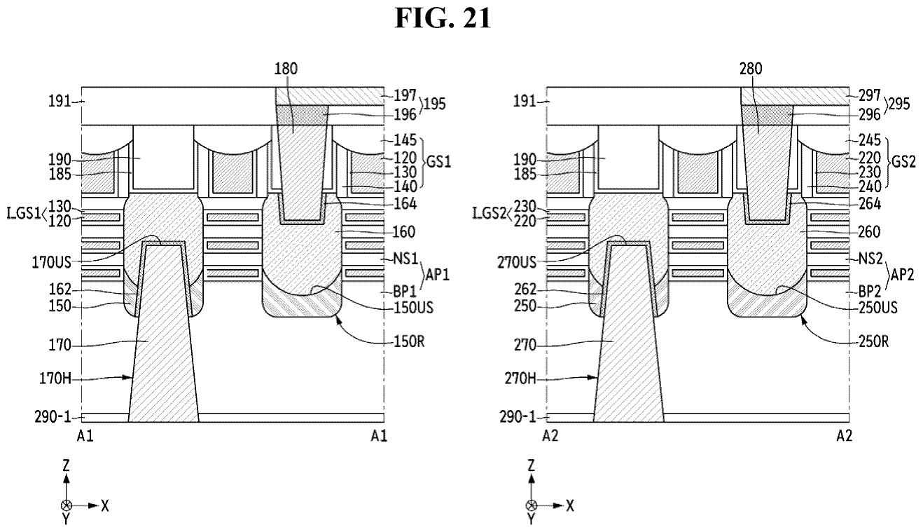

Referring to FIG. 21, a part of the first lower pattern BP1 may be removed to form a first contact hole 170H. The first contact hole 170H may extend from the first back interlayer insulating film 290_1 toward the first source/drain pattern 160. The first contact hole 170H may expose the first source/drain pattern 160. A part of the second lower pattern BP2 may be removed to form a second contact hole 270H. The second contact hole 270H may extend from the first back interlayer insulating film 290_1 toward the first source/drain pattern 160. The second contact hole 270H may expose the second source/drain pattern 260.

The first back source/drain contact 170 may fill the first contact hole 170H. The first back source/drain contact 170 may be connected to the first source/drain pattern 160. In the procedure of forming the first back source/drain contact 170, the first back contact silicide film 162 may be formed. The second back source/drain contact 270 may fill the second contact hole 270H. The second back source/drain contact 270 may be connected to the second source/drain pattern 260. In the procedure of forming the second back source/drain contact 270, the second back contact silicide film 262 may be formed.

Due to a difference in physical properties between the first source/drain pattern 160 and the second source/drain pattern 260, a difference may occur between the depth of the first contact hole 170H and the depth of the second contact hole 270H. For example, the depth of the first contact hole 170H may be deeper than the depth of the second contact hole 270H. Thus, the first back source/drain contact 170 may have a resistance value different from the target resistance value. Furthermore, a resistance difference may occur between the first back source/drain contact 170 and the second back source/drain contact 270.

Meanwhile, the semiconductor device according to some embodiments includes first source/drain spacer 150 and the second source/drain spacer 250. Each of the depth of the first contact hole 170H and the depth of the second contact hole 270H may be adjusted, by adjusting the materials of each of the first source/drain spacer 150 and the second source/drain spacer 250, the thicknesses of each of the first source/drain spacer 150 and the second source/drain spacer 250, and the like. Thus, the first back source/drain contact 170 and the second back source/drain contact 270 having a target resistance value may be formed. Furthermore, the resistance difference between the first back source/drain contact 170 and the second back source/drain contact 270 decreases, and the performance of the semiconductor device may be improved and/or enhanced.

The shape of the bottom face of the first contact hole 170H and the shape of the bottom face of the second contact hole 270H may vary by the materials of each of the first source/drain spacer 150 and the second source/drain spacer 250, the thicknesses of each of the first source/drain spacer 150 and the second source/drain spacer 250, and the like. Taking the first source/drain spacer 150 as an example, the etching rate of a first portion with a thick thickness of the first source/drain spacer 150 may be slower than a second portion with a thin thickness of the first source/drain spacer 150. Therefore, the bottom face of the first contact hole 170H formed by etching the first portion may be disposed to be lower than the bottom face of the first contact hole 170H formed by etching the second portion. Therefore, the upper face 170US of the first back source/drain contact 170 may have a step as shown in FIGS. 9 and 10.

Next, referring to FIG. 2, a second back interlayer insulating film may be formed on the first back source/drain contact 170 and the second back source/drain contact 270. For example, the first back interlayer insulating film 290_1 and the second back interlayer insulating film may be the back interlayer insulating film 290. The first back wiring line 50 and the second back wiring line 60 may be formed inside the second back interlayer insulating film.

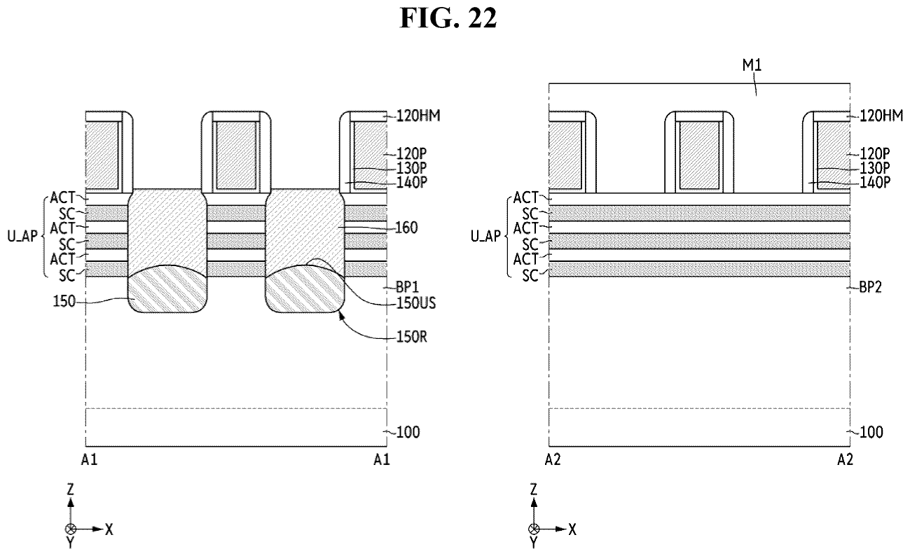

FIG. 22 is an intermediate stage diagram for explaining a method for fabricating a semiconductor device according to some embodiments. For convenience of explanation, differences from aspects explained with reference to FIGS. 1 to 21 may be mainly explained.

Referring to FIG. 22, a first rate at which the first source/drain spacer 150 grows from a portion of the substrate 100 exposed by the bottom face of the first source/drain recess 150R may be faster than a second rate at which the first source/drain spacer 150 grows from a portion of the substrate 100 exposed by the side face of the first source/drain recess 150R. In this case, the thickness of a portion of the first source/drain spacer 150 grown from the portion of the substrate 100 exposed by the bottom face of the first source/drain recess 150R may be greater than the thickness of the portion of the first source/drain spacer 150 grown from the portion of the substrate 100 exposed by the side face of the first source/drain recess 150R. In this case, the upper face 150US of the first source/drain spacer 150 may have a convex shape away from the substrate 100.

Next, the first source/drain pattern 160 may be formed. Next, the processes described with reference FIGS. 19 to 21 and FIG. 2 may be performed.

Although non-limiting example embodiments of the present disclosure have been described above with reference to the accompanying drawings, embodiments of the present disclosure are not limited to the example embodiments, and may be fabricated in various different forms. Those skilled in the art will appreciate that embodiments of the present disclosure may be provided in other specific forms without departing from the spirit and scope of the present disclosure. Accordingly, the above-described example embodiments should be understood in all respects as illustrative and not restrictive.

What is claimed is:

1. A semiconductor device comprising:
a back interlayer insulating film;
a first active pattern that extends in a first direction and is on the back interlayer insulating film;
a first gate structure that extends in a second direction, intersecting the first direction, and is on the first active pattern;
a first recess that is in the first active pattern and is on a side of the first gate structure;
a first source/drain spacer in the first recess;
a first source/drain pattern that is in the first recess and is on the first source/drain spacer;
a first back source/drain contact that extends in a third direction from the back interlayer insulating film toward the first source/drain pattern, and is connected to the first source/drain pattern;
a second active pattern that extends in the first direction and is on the back interlayer insulating film;
a second gate structure that extends in the second direction and is on the second active pattern;
a second recess that is in the second active pattern and is a side of the second gate structure;
a second source/drain spacer in the second recess;
a second source/drain pattern that is in the second recess and is on the second source/drain spacer; and
a second back source/drain contact that extends in the third direction from the back interlayer insulating film toward the second source/drain pattern, and is connected to the second source/drain pattern,
wherein the first source/drain spacer comprises a material different from a material of the second source/drain spacer.

2. The semiconductor device of claim 1, wherein
the material of the first source/drain spacer is a dielectric material, and
the material of the second source/drain spacer is silicon germanium.

3. The semiconductor device of claim 1, wherein
a minimum thickness of the first source/drain spacer is different from a minimum thickness of the second source/drain spacer.

4. The semiconductor device of claim 1, wherein
at least one from among an upper face of the first source/drain spacer and an upper face of the second source/drain spacer comprises a concave portion.

5. The semiconductor device of claim 1, wherein
at least one from among an upper face of the first source/drain spacer and an upper face of the second source/drain spacer comprises a convex portion.

6. The semiconductor device of claim 1, wherein
at least one from among the first source/drain spacer and the second source/drain spacer comprises a first spacer film and a second spacer film that are stacked in order.

7. The semiconductor device of claim 1, wherein
an upper face of the first back source/drain contact is on a same plane as an upper face of the second back source/drain contact.

8. The semiconductor device of claim 1, wherein
an upper face of the first back source/drain contact is on a different plane from an upper face of the second back source/drain contact.

9. The semiconductor device of claim 1, wherein
at least one from among an upper face of the first back source/drain contact and an upper face of the second back source/drain contact comprises a step.

10. The semiconductor device of claim 1, wherein
at least one from among an upper face of the first back source/drain contact and an upper face of the second back source/drain contact comprises a convex portion and a concave portion.

11. The semiconductor device of claim 1, wherein
a bottom face of the first recess is defined by the first active pattern, and a bottom face of the second recess is defined by the second active pattern.

12. The semiconductor device of claim 1, further comprising:
a back insertion insulating film on the back interlayer insulating film,
wherein the first active pattern and the second active pattern are on the back insertion insulating film, and
wherein a bottom face of the first recess and a bottom face of the second recess are defined by the back insertion insulating film.

13. A semiconductor device comprising:
a back interlayer insulating film;
a first back wiring line in the back interlayer insulating film;
a second back wiring line in the back interlayer insulating film;
a first active pattern that extends in a first direction and is on the first back wiring line;
a first gate structure that extends in a second direction, interesting the first direction, and is on the first active pattern;
a first source/drain pattern that comprises an impurity of a first conductivity type and is on a side of the first gate structure;
a first source/drain spacer that extends along a bottom face of the first source/drain pattern;
a first back source/drain contact that connects the first back wiring line and the first source/drain pattern;
a second active pattern that extends in the first direction and is on the second back wiring line;
a second gate structure that extends in the second direction and is on the second active pattern;
a second source/drain pattern that comprises an impurity of a second conductivity type, different from the first conductivity type, and is on a side of the second gate structure;
a second source/drain spacer that extends along a bottom face of the second source/drain pattern; and
a second back source/drain contact that connects the second back wiring line and the second source/drain pattern.

14. The semiconductor device of claim 13, wherein
the first source/drain spacer comprises a material different from a material of the second source/drain spacer.

15. The semiconductor device of claim 13, wherein
the first source/drain spacer comprises a material that is the same as a material of the second source/drain spacer, and
a minimum thickness of the first source/drain spacer is different from a minimum thickness of the second source/drain spacer.

16. The semiconductor device of claim 13, wherein
an upper face of the first back source/drain contact is on a same plane as an upper face of the second back source/drain contact.

17. A semiconductor device comprising:
a back interlayer insulating film;
a first back wiring line in the back interlayer insulating film;
a second back wiring line in the back interlayer insulating film;
a plurality of first sheet patterns spaced apart from each other on the first back wiring line;
a first gate structure that surrounds the plurality of first sheet patterns;
a first source/drain pattern that is connected to the plurality of first sheet patterns, comprises an impurity of a first conductivity type, and is on a side of the first gate structure;
a first source/drain spacer that extends along a bottom face of the first source/drain pattern;
a first back source/drain contact that connects the first back wiring line and the first source/drain pattern;
a plurality of second sheet patterns spaced apart from each other on the second back wiring line;
a second gate structure that surrounds the plurality of second sheet patterns;
a second source/drain pattern that is connected to the plurality of second sheet patterns, comprises an impurity of a second conductivity type different from the first conductivity type, and is on a side of the second gate structure;
a second source/drain spacer that extends along a bottom face of the second source/drain pattern; and
a second back source/drain contact that connects the second back wiring line and the second source/drain pattern,
wherein the first source/drain spacer comprises a material different from a material of the second source/drain spacer.

18. The semiconductor device of claim 17, wherein
the material of the first source/drain spacer is a dielectric material,
the material of the second source/drain spacer is silicon germanium.

19. The semiconductor device of claim 17, further comprising:
a first lower pattern between the first back wiring line and the plurality of first sheet patterns; and
a second lower pattern between the second back wiring line and the plurality of second sheet patterns,
wherein the first source/drain spacer is in contact witch the first lower pattern, and
wherein the second source/drain spacer is in contact with the second lower pattern.

20. The semiconductor device of claim 17, further comprising:
a back insertion insulating film on the back interlayer insulating film,
wherein the plurality of first sheet patterns and the plurality of second sheet patterns are on the back insertion insulating film, and
wherein the first source/drain spacer and the second source/drain spacer is in contact with the back insertion insulating film.
